(19) United States
(12) Patent Application Publication
(10) Pub. No.: US 2014/0162132 A1
(43) Pub. Date: Jun. 12, 2014

(54) POSITIVE ELECTRODE ACTIVE MATERIAL AND MANUFACTURING METHOD THEREOF, POSITIVE ELECTRODE, BATTERY, BATTERY PACK, ELECTRONIC DEVICE, ELECTRIC VEHICLE, POWER STORAGE DEVICE, AND POWER SYSTEM

(71) Applicant: Sony Corporation, Tokyo (JP)

(72) Inventors: Yoshiyuki Ishii, Kanagawa (JP); Masaaki Sekine, Kanagawa (JP); Hidetoshi Honda, Kanagawa (JP); Takashi Murakami, Kanagawa (JP)

(73) Assignee: Sony Corporation, Tokyo (JP)

(21) Appl. No.: 14/088,990

(22) Filed: Nov. 25, 2013

(30) Foreign Application Priority Data
Dec. 6, 2012 (JP) 2012-267544

(51) Int. Cl. H01M 4/131; C23C 16/40; H02J 7/00; B60R 16/033; H01M 4/36; H01M 4/62

(52) U.S. Cl. CPC H01M 4/131; H01M 4/366; H01M 4/62; H02J 7/007; B60R 16/033; C23C 16/403
USPC 429/231.95; 320/128; 307/9.1; 427/78

(57) ABSTRACT

There is provided a positive electrode active material including a particle containing a lithium-containing compound, and an inorganic oxide layer provided on at least part of a surface of the particle. An average thickness of the inorganic oxide layer falls within a range of 0.2 nm or more and 5 nm or less.

### CROSS REFERENCE TO RELATED APPLICATIONS

This application claims the benefit of Japanese Priority Patent Application JP 2012-267544 filed Dec. 6, 2012, the entire contents of which are incorporated herein by reference.

### BACKGROUND

The present technology relates to a positive electrode active material and a manufacturing method thereof, a positive electrode, a battery, a battery pack, an electronic device, an electric vehicle, a power storage device, and a power system, and specifically, relates to a positive electrode active material in which the state of particle surfaces is reformed.

Striking development of the mobile electronics technology in recent years allows electronic devices such as a mobile phone and a notebook-type computer to spread widely. As batteries supplying power to such electronic devices, lithium ion secondary batteries which have excellent energy density are generally utilized.

As a positive electrode active material of the lithium ion secondary battery, particles of lithium transition metal composite oxide including LiCoO₂ or LiNiO₂ are utilized widely. Various technologies of reforming the state of the particle surfaces of the lithium transition metal composite oxide are proposed in recent years.

Hereafter, generally proposed technologies of surface reformation are shown. Japanese Patent Laid-Open No. 2002-164053 discloses a technology of forming a surface treatment layer on the surface of a core including a lithium compound due to a sol-gel method. Japanese Patent Laid-Open No. 10-162825 discloses a technology of producing a composite particle by causing small particles composed of lithium metal-containing oxide to adhere on the surface of a mother particle composed of lithium metal-containing oxide to be integrated using a mechanochemical method.

### SUMMARY

The existing surface reformation technologies, however, sometimes cause the battery capacity to decrease. Therefore, a technology capable of suppressing decrease in battery capacity while reforming the state of particle surfaces is desired.

Accordingly, it is desirable to provide a positive electrode active material allowing decrease in battery capacity to be suppressed while reforming the state of particle surfaces and a manufacturing method of the same, and a positive electrode, a battery, a battery pack, an electronic device, an electric vehicle, a power storage device and power system using the positive electrode active material.

According to an embodiment of the present disclosure, there is provided a positive electrode active material including a particle containing a lithium-containing compound, and an inorganic oxide layer provided on at least part of a surface of the particle. An average thickness of the inorganic oxide layer falls within a range of 0.2 nm or more and 5 nm or less.

According to an embodiment of the present disclosure, there is provided a positive electrode including a particle containing a lithium-containing compound, and an inorganic oxide layer provided on at least part of a surface of the particle. An average thickness of the inorganic oxide layer falls within a range of 0.2 nm or more and 5 nm or less.

According to an embodiment of the present disclosure, there is provided a battery including a positive electrode, a negative electrode, and an electrolyte. The positive electrode includes a particle containing a lithium-containing compound, and an inorganic oxide layer provided on at least part of a surface of the particle. An average thickness of the inorganic oxide layer falls within a range of 0.2 nm or more and 5 nm or less.

According to an embodiment of the present disclosure, there is provided a manufacturing method of a positive electrode active material, including forming an inorganic oxide layer whose average thickness falls within a range of 0.2 nm or more and 5 nm or less by depositing monolayers on a surface of a particle containing a lithium-containing compound.

A battery pack, an electronic device, an electric vehicle, a power storage device and a power system according to the present technology include the positive electrode active material according to the first technology, the positive electrode according to the second technology and the battery according to the third technology.

In the present technology, the inorganic oxide layer is provided on at least part of the particle surface and the average thickness thereof is set within a range of 0.2 nm or more and 5 nm or less. When the average thickness is smaller than 0.2 nm, the effect of surface reformation tends to decrease. On the other hand, when the average thickness exceeds 5 nm, the battery capacity tends to decrease.

As described above, according to the present technology, decrease in battery capacity can be suppressed while reforming the state of particle surfaces.

### BRIEF DESCRIPTION OF THE DRAWINGS

FIG. 1A is a cross-sectional view showing one exemplary configuration of a positive electrode active material according to a first embodiment of the present technology;

FIG. 1B is a cross-sectional view showing another exemplary configuration of the positive electrode active material according to the first embodiment of the present technology;

FIG. 2 is a schematic diagram showing one configuration of an inorganic oxide layer;

FIG. 3A is a cross-sectional view showing one exemplary configuration of a positive electrode active material according to a first variation;

FIG. 3B is a cross-sectional view showing another exemplary configuration of the positive electrode active material according to the first variation;

FIG. 4 is a cross-sectional view showing one exemplary configuration of a non-aqueous electrolyte secondary battery according to a second embodiment of the present technology;

FIG. 5 is an enlarged cross-sectional view showing part of a wound electrode body shown in FIG. 4;

FIG. 6 is an exploded perspective view showing one exemplary configuration of a non-aqueous electrolyte secondary battery according to a third embodiment of the present technology;

FIG. 7 is a cross-sectional view taken along the line VII-VII of the wound electrode body shown in FIG. 6;

FIG. 8 is a block diagram showing one exemplary configuration of a battery pack according to a fourth embodiment of the present technology;

FIG. 9 is a schematic diagram showing an example in which a non-aqueous electrolyte secondary battery according to the present technology is applied to a power storage system for a house;

FIG. 10 is a schematic diagram showing one configuration of a hybrid vehicle employing a series hybrid system to which the present technology is applied;

FIG. 11A is a diagram showing relationship between thicknesses of inorganic oxide layers and initial capacities regarding coin cells in Examples 1-1 to 1-5 and Comparative Examples 1-1 to 1-3;

FIG. 11B is a diagram showing relationship between average coverage ratios and capacity maintaining ratios regarding coin cells in Examples 2-1 to 2-3 and Comparative Example 2-1; and

FIG. 12 is a diagram showing relationship between average coverage ratios and initial capacities regarding coin cells in Examples 3-1 to 3-5 and Comparative Example 3-1.

### DETAILED DESCRIPTION OF THE EMBODIMENT(S)

Hereinafter, preferred embodiments of the present disclosure will be described in detail with reference to the appended drawings. Note that, in this specification and the appended drawings, structural elements that have substantially the same function and structure are denoted with the same reference numerals, and repeated explanation of these structural elements is omitted. Note that the description will be made in the following order.

### 1. First Embodiment (Example of Positive Electrode Active Material)

### 2. Second Embodiment (Example of Cylinder Type Battery)

### 3. Third Embodiment (Example of Flat Type Battery)

### 4. Fourth Embodiment (Example of Battery Pack)

### 5. Fifth Embodiment (Example of Power Storage System)

### 1. First Embodiment

### Configuration of Positive Electrode Active Material

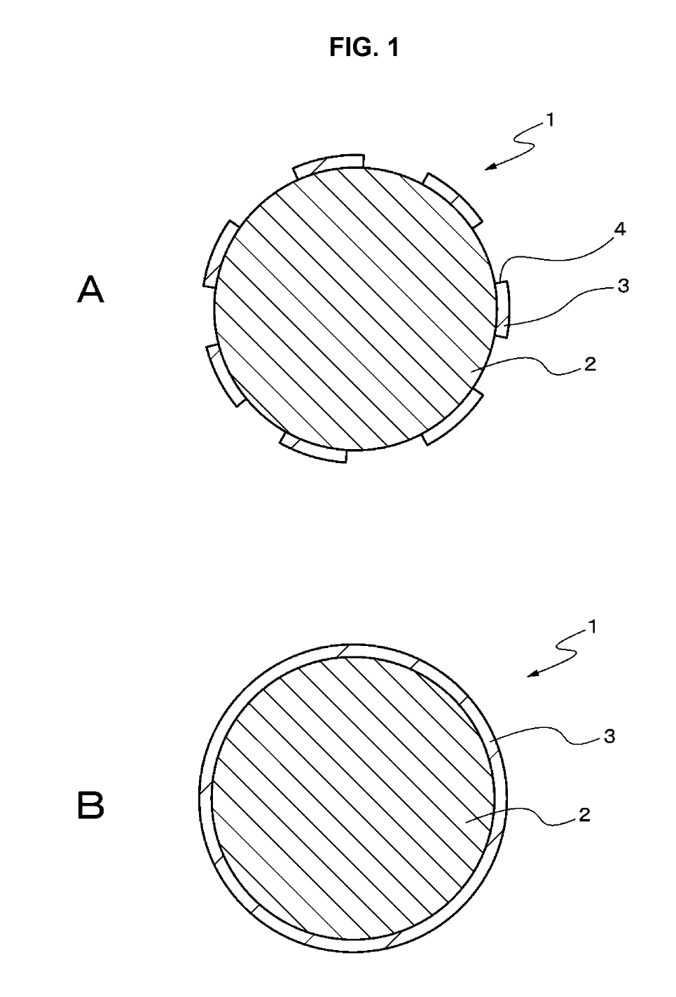

FIG. 1A is a cross-sectional view showing one exemplary configuration of a positive electrode active material according to a first embodiment of the present technology. The positive electrode active material is powder including surface covering composite particles 1. The surface covering composite particle 1 includes a positive electrode active material particle 2 as a core particle and an inorganic oxide layer 3 which is provided on its surface as a covering layer.

Part of the surface of the positive electrode active material particle 2 may be exposed from the inorganic oxide layer 3. More specifically, the inorganic oxide layer 3 may have one or two or more opening parts 4 and the surface of the positive electrode active material particle 2 may be exposed from the opening parts 4, for example. Moreover, the inorganic oxide layer 3 may have a form of islands or the like which are dotted on the surface of the positive electrode active material particle 2. An exposure part exposed from the surface of the positive electrode active material particle 2 includes an exposure part formed in a covering processing step of the inorganic oxide layer 3 and an exposure part formed caused by crack or the like of the surface covering composite particle 1 in a battery producing step after the covering processing step. By exposing the surface of the positive electrode active material particle 2 as above, lithium ions can transfer between the positive electrode active material particle 2 and an electrolyte through the exposure portion, this not being prohibited by the inorganic oxide layer 3. Accordingly, the surface covering composite particle 1 can maintain charge transfer resistance equivalent to a positive electrode active material particle whose surface is not covered with the inorganic oxide layer 3 (hereinafter, referred to as “non-covering particle”), and decrease of initial battery capacity caused by resistance elevation can be suppressed. Examples of the form of the opening part 4 provided in the inorganic oxide layer 3 include a substantially circle form, a substantially ellipse form, an indeterminate form and the like, whereas they are not limited to these forms particularly.

In FIG. 1A, an example in which part of the surface of the positive electrode active material particle 2 is exposed from the inorganic oxide layer 3 is shown, whereas the configuration of the surface covering composite particle 1 is not limited to this example. As shown in FIG. 1B, a configuration may be employed in which the entire surface of the positive electrode active material particle 2 is completely covered with the inorganic oxide layer 3. Hereinafter, a state in which the entire surface of the positive electrode active material particle 2 is completely covered with the inorganic oxide layer 3 is referred to as “complete covering state” and a state in which the entire surface of the positive electrode active material particle 2 is partially covered with the inorganic oxide layer 3 is referred to as “incomplete covering state”.

As well as the surface covering composite particle (first particle) 1, the positive electrode active material may further include a positive electrode active material particle (second particle) 2 on whose surface the inorganic oxide layer 3 is not provided and whose entire surface is exposed, as necessary. Moreover, the positive electrode active material may include two or more kinds of surface covering composite particles 1 as necessary. Examples of the two or more kinds of surface covering composite particles 1 include, for example, surface covering composite particles 1 different in average thickness of the inorganic oxide layer 3, surface covering composite particles 1 different in covering state of the inorganic oxide layer 3, surface covering composite particles 1 different in constituent material of the positive electrode active material particle 2 as a core particle, and surface covering composite particles 1 different in particle size distribution. Herein examples of the surface covering composite particles 1 different in covering state of the inorganic oxide layer 3 include, for example, surface covering composite particles 1 in the complete covering state and the incomplete covering state of the covering states of the inorganic oxide layer 3, and surface covering composite particles 1 different in average coverage ratio.

### (Positive Electrode Active Material Particle)

The positive electrode active material particle 2 is, for example, a primary particle or a secondary particle which is an aggregate of primary particles. Examples of the form of the positive electrode active material particle 2 include, for example, a globe form, an ellipsoid form, a needle form, a plate form, a scale form, a tube form, a wire form, a stick form (rod form), an indeterminate form and the like, whereas they are not limited to these particularly. In addition, two or more kinds of particles with the above-mentioned forms may be combined to be used. Herein, the globe form includes not only a spherical form but also a form which is slightly flat or distorted compared with the strict spherical form, a form which is obtained by forming unevenness on the surface of the strict spherical form, a form obtained by combining any of these forms, and the like. The ellipsoid form includes not only a strict ellipsoid form but also a form which is slightly flat or distorted compared with the strict ellipsoid form, a form which is obtained by forming unevenness on the surface of the strict ellipsoid form, a form obtained by combining any of these forms, and the like.

The positive electrode active material particle 2 contains one kind or two or more kinds of positive electrode materials capable of intercalating and deintercalating lithium. As such positive electrode materials, lithium-containing compounds such, for example, as lithium oxide, lithium phosphate, lithium sulfide, and an intercalation compound containing lithium are suitable and two or more kinds of these may be mixed to be used. In order to increase the energy density, lithium-containing compounds containing lithium, a transition metal element, and oxygen (O) are preferable. Examples of such a lithium-containing compound include, for example, a lithium composite oxide having a structure of a layered rock salt type represented by formula (A), and a lithium complex phosphate salt having a structure of an olivine type represented by formula (B). The lithium-containing compound is still preferable to contain at least one member selected from the group consisting of cobalt (Co), nickel (Ni), manganese (Mn) and iron (Fe) as a transition metal element. Examples of such a lithium-containing compound include, for example, a lithium composite oxide having a structure of a layered rock salt type represented by formula (C), (D) or (E), a lithium composite oxide having a structure of a spinel type represented by formula (F), and a lithium composite phosphate salt having a structure of an olivine type represented by formula (G). Specific examples thereof include LiNi_{0.50}Co_{0.20}Mn_{0.30}O₂, LiₐCoO₂ (a≈1), Li_{b}NiO₂ (b≈1), Li_{c1}Ni_{c2}Co_{1-c2}O₂ (c1≈1, 0<c2<1), Li_{d}Mn₂O₄(d≈1), and LiₑFePO₄(e≈1).

LiₚNi_{(1-q-r)}Mn_{q}M1ᵣO_{(2-y)}X_{z} (A)

(where in the formula (A), M1 represents at least one of elements selected from 2 to 15 group elements except for nickel (Ni) and manganese (Mn); X represents at least one of 16 and 17 group elements except for oxygen (O); p, q, r, y, and z are values in ranges of 0≦p≦1.5, 0≦q≦1.0, 0≦r≦1.0, −0.10≦y≦0.20, and 0≦z≦0.2).

LiₐM2_{b}PO₄ (B)

(where in the formula (B), M2 represents at least one of elements selected from 2 to 15 group elements. a, b are values in ranges of 0≦a≦2.0, 0.5≦b≦2.0).

Li_{f}Mn_{(1-g-h)}Ni_{g}M3ₕO(₂₋ⱼ)Fₖ (C)

(where in the formula (C), M3 represents at least one selected from the group consisting of cobalt (Co), magnesium (Mg), aluminum (Al), boron (B), titanium (Ti), vanadium (V), chromium (Cr), iron (Fe), copper (Cu), zinc (Zn), zirconium (Zr), molybdenum (Mo), tin (Sn), calcium (Ca), strontium (Sr), and tungsten (W); f, g, h, j, and k are values in ranges of 0.8≦f≦1.2, 0≦g<0.5, 0≦h≦0.5, g+h<1, and −0.1≦j≦0.2, 0≦k≦0.1. Note that the composition of lithium differs depending on the state of charge/discharge, and the value off represents a value in a complete discharge state).

LimNi(1−n)M4nO(2−p)Fq (D)

(where in the formula (D), M4 represents at least one selected from the group consisting of cobalt (Co), manganese (Mn), magnesium (Mg), aluminum (Al), boron (B), titanium (Ti), vanadium (V), chromium (Cr), iron (Fe), copper (Cu), zinc (Zn), molybdenum (Mo), tin (Sn), calcium (Ca), strontium (Sr), and tungsten (W); m, n, p, and q are values in ranges of 0.8≦m≦1.2, 0.005≦n≦0.5, −0.1≦p≦0.2, and 0≦q≦0.1. Note that the composition of lithium differs depending on the state of charge/discharge, and the value of m represents a value in a complete discharge state).

LirCo(1−s)M5sO(2−t)Fu (E)

(where in the formula (E), M5 represents at least one selected from the group consisting of nickel (Ni), manganese (Mn), magnesium (Mg), aluminum (Al), boron (B), titanium (Ti), vanadium (V), chromium (Cr), iron (Fe), copper (Cu), zinc (Zn), molybdenum (Mo), tin (Sn), calcium (Ca), strontium (Sr), and tungsten (W); r, s, t, and u are values in ranges of 0.8≦r≦1.2, 0≦s<0.5, −0.1≦t≦0.2, and 0≦u≦0.1. Note that the composition of lithium differs depending on the state of charge/discharge, and the value of r represents a value in a complete discharge state).

LiᵥMn_{2-w}M6_{w}OₓF_{y} (F)

(where in the formula (F), M6 represents at least one selected from the group consisting of cobalt (Co), nickel (Ni), magnesium (Mg), aluminum (Al), boron (B), titanium (Ti), vanadium (V), chromium (Cr), iron (Fe), copper (Cu), zinc (Zn), molybdenum (Mo), tin (Sn), calcium (Ca), strontium (Sr), and tungsten (W); v, w, x, and y are values in ranges of 0.9≦v≦1.1, 0≦w≦0.6, 3.7≦x≦4.1, and 0≦y≦0.1. Note that the composition of lithium differs depending on the state of charge/discharge, and the value of v represents a value in a complete discharge state).

Li_{z}M7PO₄ (G)

(where in the formula (G), M7 represents at least one selected from the group consisting of cobalt (Co), manganese (Mn), iron (Fe), nickel (Ni), magnesium (Mg), aluminum (Al), boron (B), titanium (Ti), vanadium (V), niobium (Nb), copper (Cu), zinc (Zn), molybdenum (Mo), calcium (Ca), strontium (Sr), tungsten (W), and zirconium (Zr); z is a value in ranges of 0.9≦z≦1.1. Note that the composition of lithium differs depending on the state of charge/discharge, and the value of z represents a value in a complete discharge state).

Other than these, the examples of the positive electrode materials capable of intercalating and deintercalating lithium also include inorganic compounds, which do not contain lithium, such as MnO₂, V₂O₅, V₆O₁₃, NiS and MoS.

### (Inorganic Oxide Layer 3)

### (Composition)

The inorganic oxide layer 3 is, for example, a covering layer covering at least part of the surface of the positive electrode active material particle 2. The inorganic oxide layer 3 has, for example, a crystal structure. The inorganic oxide layer 3 is, for example, a metal oxide layer containing metal oxide. The metal oxide contains, for example, at least one member of metal selected from the group consisting of aluminum (Al), titanium (Ti), silicon (Si), vanadium (V), zirconium (Zr), niobium (Nb), tantalum (Ta), magnesium (Mg), boron (B), zinc (Zn), tungsten (W), tin (Sn), lithium (Li), barium (Ba) and strontium (Sr). Herein, the metal is supposed to include semi-metal.

More specifically, the metal oxide includes at least one member of metal oxide selected from the group consisting of aluminum oxide (alumina), titanium oxide (titania), silicon oxide (silica), vanadium oxide, zirconium oxide (zirconia), niobium oxide, tantalum oxide, magnesium oxide, boron oxide, zinc oxide, tungsten oxide, tin oxide, hafnium oxide, lanthanum oxide, yttrium oxide, cerium oxide, scandium oxide, erbium oxide, indium oxide, lithium titanate, barium titanate and strontium titanate.

Examples of a method of composition analysis of the inorganic oxide layer 3 include, for example, a method of Inductively Coupled Plasma Atomic Emission Spectroscopy (ICP-AES), a method of a Time-of-flight Secondary Ion Mass Spectrometer (TOF-SIMS), and the like.

### (Average Thickness)

An average thickness D of the inorganic oxide layer 3 falls within a range of 0.2 nm or more and 5 nm or less. When the average thickness is smaller than 0.2 nm, an effect of surface reformation due to the inorganic oxide layer 3 (more specifically, an effect of improvement of a capacity maintaining ratio) is not attained. On the other hand, when the average thickness exceeds 5 nm, the initial battery capacity tends to decrease.

The average thickness D of the inorganic oxide layer 3 can be obtained as follows. In the powder of the positive electrode active material, 10 surface covering composite particles 1 are selected at random, individual cross-sectional TEM (Transmission Electron Microscope) images of these surface covering composite particles 1 are acquired, and thicknesses d₁, d₂, . . . , d₁₀ are obtained. Next, the obtained thicknesses d₁, d₂, . . . , d₁₀ undergo simple averaging (arithmetic mean) to obtain the average thickness D of the inorganic oxide layer 3.

### (Layer Configuration)

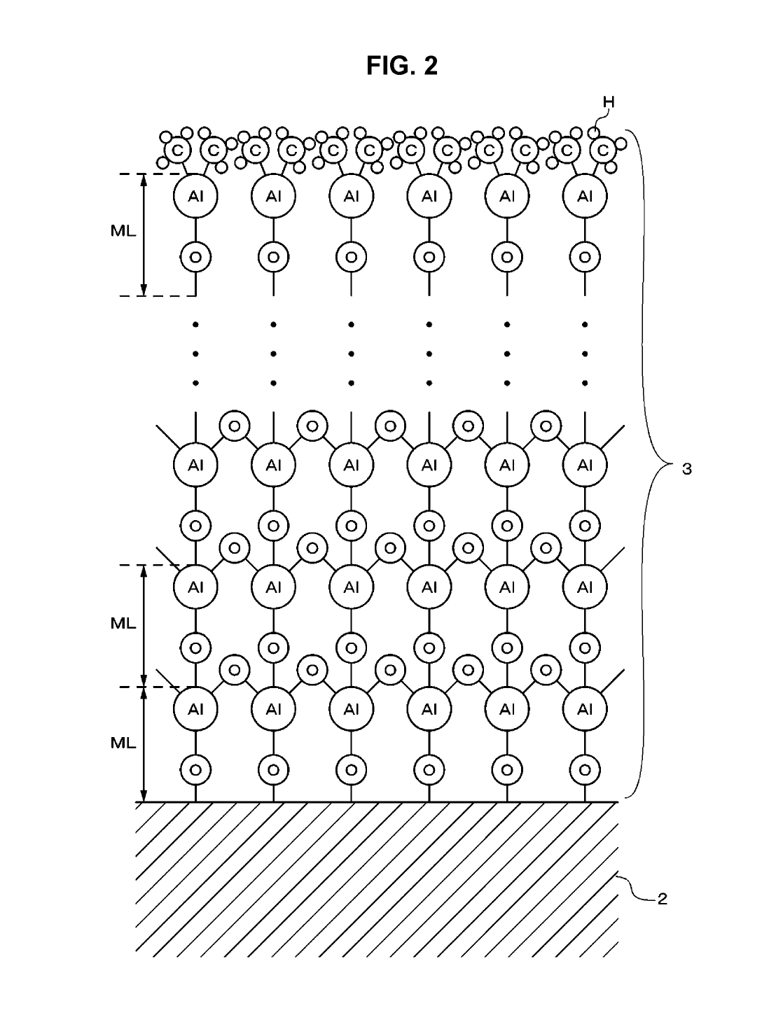

FIG. 2 is a schematic diagram showing one configuration of the inorganic oxide layer 3. It is preferable for the inorganic oxide layer 3 to be configured of deposited monolayers ML. This is because the surface of the positive electrode active material particle 2 can be covered with the inorganic oxide layer 3 high in film thickness uniformity. FIG. 2 shows an example of the inorganic oxide layer 3 being a metal oxide layer made of aluminum oxide. It can be confirmed whether or not the inorganic oxide layer 3 is configured of deposited monolayers ML by acquiring a cross-sectional TEM image of the surface covering composite particle 1.

### (Number of Deposition)

An average number of deposition of the monolayers ML preferably falls within a range of 2 layers or more and 50 layers or less. When the average number of deposition is smaller than 2 layers, the effect of surface reformation due to the inorganic oxide layer 3 tends to decrease. On the other hand, when the average number of deposition exceeds 50 layers, the initial battery capacity tends to decrease. Herein, the monolayer ML means a single molecular layer of inorganic oxide (for example, MOₓ where M: metal) but does not a single molecular layer of an inorganic substance (for example, metal) or oxygen. When the inorganic oxide layer 3 is configured of aluminum oxide, the monolayer ML means a single molecular layer of aluminum oxide (AlOX) but does not a single molecular layer of aluminum or oxygen, as shown in FIG. 2

The average number of deposition of the monolayers ML is obtained as follows. First, the composition of the inorganic oxide layer 3 is analyzed. Next, the thickness of one monolayer ML is identified based on the composition as an analysis result. For example, when it is identified that the inorganic oxide layer 3 is configured of aluminum oxide (alumina) based on the analysis result, it can be identified that the thickness of one monolayer ML is approximately 0.1 nm. Examples of a method for the composition analysis of the inorganic oxide layer 3 include, for example, ICP-AES, TOF-SIMS and the like. Next, as mentioned above, the average thickness of the inorganic oxide layer 3 is obtained. Next, the average number of deposition of the monolayers ML is calculated by dividing the average thickness of the inorganic oxide layer 3 by the thickness of one monolayer ML.

### (Average Coverage Ratio)

An average coverage ratio of the surface covering composite particle 1 preferably falls within a range of 30% or more and 100% or less and still preferably falls within a range of 30% or more and 96% or less. When the average coverage ratio is smaller than 30%, the capacity maintaining ratio tends to decrease. On the other hand, when the average coverage ratio exceeds 96%, the initial capacity tends to decrease, the capacity maintaining ratio being high.

The average coverage ratio of the surface covering composite particle 1 can be calculated by the following expression.

Average coverage ratio[%]=((actual mass of the inorganic oxide layer 3)/(mass of the inorganic oxide layer 3 in the coverage ratio being 100%))×100=(x/(A(M−x)·n·p))×10⁵

M [g]: Mass of the powder of the positive electrode active material used for ICP-AES analysis

x [g]: Actual mass of the inorganic oxide layer 3 in the powder of the positive electrode active material used for ICP-AES analysis

A [m²/g]: Specific surface area of the positive electrode active material particle 2

n [nm]: Average thickness of the inorganic oxide layer 3 obtained by cross-sectional TEM observation

ρ [g/cm³]: Density of the inorganic oxide layer 3 evaluated using an X-ray Reflection (XRR) method

### (Actual Weight x of Inorganic Oxide Layer)

Specifically, the actual weight x of the inorganic oxide layer 3 is obtained as follows. First, mass M of the powder of the positive electrode active material is weighed. Next, the powder of the positive electrode active material is dissolved in an acid solution, the solution is analyzed by ICP-AES and a mass ratio A:B [wt. %] between the positive electrode active material particle 2 which is the core particle and the inorganic oxide layer 3 is quantified.

Next, the actual mass of the inorganic oxide layer 3 is calculated by the following expression.

Actual mass of the inorganic oxide layer 3 [g]=(mass M of the powder of the positive electrode active material)×(mass ratio B of the inorganic oxide layer 3)

### (Specific Surface Area A of Positive Electrode Active Material Particle)

The specific surface area of the positive electrode active material particle 2 is obtained by a BET method (Brunauer-Emmett-Teller method). In addition, when the average thickness of the inorganic oxide layer 3 is exceedingly thin, for example, approximately 0.2 nm to 5 nm, the specific surface areas of the positive electrode active material particle 2 and the surface covering composite particle 1 obtained by the BET method can be regarded as being substantially equal to each other.

### (Average Thickness n of Inorganic Oxide Layer)

The average thickness n of the inorganic oxide layer 3 is obtained similarly to the above-mentioned average thickness D of the inorganic oxide layer 3.

### (Density ρ of Inorganic Oxide Layer)

The density ρ of the Al₂O₃ layer is obtained using XRR as follows. First, X-rays are incident on the surface of the inorganic oxide layer 3 by a very shallow angle, and an intensity profile of the X-rays which are reflected in directions of the mirror plane opposite to the incident angle is measured. Next, the profile obtained by the measurement is compared with the simulation result and the simulation parameters are optimized to determine the density of the inorganic oxide layer 3.

### [Manufacturing Method of Positive Electrode Active Material]

Next, one example of a manufacturing method of the positive electrode active material having the above-mentioned configuration is described. In the manufacturing method, the inorganic oxide layer 3 is formed by repeatedly depositing monolayers ML of inorganic oxide on the surface of the positive electrode active material particle 2. As the method of repeatedly depositing monolayers ML, an Atomic Layer Deposition (ALD) method is used. Herein, a case where the inorganic oxide layer 3 is formed using two kinds of reaction substances as feedstock is described, whereas the feedstock is not limited to two kinds of reaction substances but three or more kinds of reaction substances may be used.

### (First Step)

First, vapor of a first reaction substance is supplied to a deposition chamber of an ALD apparatus and allowed to undergo chemical absorption on the surface of the positive electrode active material particle 2. The first reaction substance (first precursor) contains oxygen (O) as a constituent element of the inorganic oxide layer 3. As the first reaction substance, for example, water (H₂O) can be used.

### (Second Step)

Next, inert gas (purge gas) is supplied to the deposition chamber of the ALD apparatus and excess first reaction substance and byproduced substance are evacuated. As the inert gas, for example, N₂ gas, Ar gas or the like can be used.

### (Third Step)

Next, vapor of a second reaction substance (second precursor) is supplied to the deposition chamber of the ALD apparatus and allowed to react with first reaction substance absorbed on the surface of the positive electrode active material particle 2. The second reaction substance contains an inorganic material such as metal which is a constituent element of the inorganic oxide layer 3. As the second reaction substance, for example, trimethylaluminum, triisobutylaluminum, titanium tetrachloride, tetrakis(ethylmethylamino)titanium(IV), tetrakis(dimethylamido)titanium(IV), silicon tetrachloride, methylsilane, hexamethyldisilane, dodecamethylcyclohexasilane, tetramethylsilane, tetraethylsilane, bis(cyclopentadienyl)vanadium(II), tetrakis(ethylmethylamido)zirconium(IV), tetrakis(dimethylamido)zirconium(IV), bis(cyclopentadienyl)niobium(IV) dichloride, pentakis(dimethylamino)tantalum(V), bis(cyclopentadienyl)magnesium (II), tris(pentafluorophenyl)borane, triphenylborane, diethylzinc, tungsten hexacarbonyl, bis(isopropylcyclopentadienyl)tungsten(IV) dihydride, bis(cyclopentadienyl)tungsten (IV) dihydride, tetravinyltin, tetramethyltin, trimethyl(phenyl)tin, or the like can be used solely or a combination of two or more kinds of these is used.

### (Fourth Step)

Next, inert gas (purge gas) is supplied to the deposition chamber of the ALD apparatus and excess second reaction substance and byproduced substance are evacuated. As the inert gas, for example, N₂ gas, Ar gas or the like can be used.

The above-mentioned first to fourth steps being one cycle (hereinafter, this cycle is referred to as an “ALD cycle”), the monolayers ML can be repeatedly deposited by repeating the cycle. Accordingly, by adjusting a cycle number of the ALD cycles, a desired thickness of the inorganic oxide layer 3 can be formed. It is preferable for the cycle number to fall within a range of 2 or more and 50 or less. In addition, a single molecular layer formed in one ALD cycle corresponds to the above-mentioned one monolayer ML. As above, the desired positive electrode active material is obtained.

In addition, the average coverage ratio of the surface covering composite particle 1 can be configured within a desired range by adjusting a coordination number of the positive electrode active material particle 2 in the powder. Herein, the coordination number is the number of contact points and/or the number of bonding parts present on the surface of the positive electrode active material particle 2 which comes into contact with and/or bonds with others. Since the contact portions and/or the bonding portions of the positive electrode active material particle 2 are not exposed to any of the vapors of the first reaction substance and the second reaction substance, a state in which any monolayer ML is not deposited is attained in the contact portions and/or the bonding portions. Due to this, when the positive electrode active material particles which come into contact with and/or bond with one another are separated from one another after the inorganic oxide layer 3 is formed, the contact portions and/or the bonding portions of the particle become the opening parts 4 and the like of the inorganic oxide layer 3, and the surface of the positive electrode active material particle 2 is exposed via these opening parts 4 and the like.

Examples of a method of adjusting the coordination number of the positive electrode active material particle include, for example, a method of adjusting a containing amount of the positive electrode active material particles 2 contained in the deposition chamber of the ALD apparatus, and a method of adjusting an adhering state or an aggregating state between the positive electrode active material particles. In addition, as the containing amount of the positive electrode active material particles 2 contained in the deposition chamber of the ALD apparatus increases, the coordination number of the positive electrode active material particle 2 in the powder tends to increase.

### [Effects]

According to the first embodiment, the inorganic oxide layer 3 is provided on the surface of the positive electrode active material particle 2, and the average thickness thereof is configured within a range of 0.2 nm or more and 5 nm or less. When the average thickness is smaller than 0.2 nm, an effect of surface reformation due to the inorganic oxide layer 3 tends to decrease. On the other hand, when the average thickness exceeds 5 nm, the initial battery capacity tends to decrease.

Since the ALD method has high capability of film thickness controlling, the inorganic oxide layer 3 that is uniform can be formed on the surface of the positive electrode active material particle 2 by a necessary amount. Due to this, the following effects can be attained. Decrease of the energy density of the battery caused by the inorganic oxide layer 3 provided on the surface of the positive electrode active material particle 2 can be suppressed. Increase of Li ion reaction resistance caused by the inorganic oxide layer 3 can be suppressed. Change in particle size distribution caused by the inorganic oxide layer 3 provided on the surface of the positive electrode active material particle 2 can be suppressed. The absolute amount of the inorganic oxide layer 3 as the covering layer can be decreased. Accordingly, the surface covering composite particle 1 can be made low in costs. When the covering state of the surface covering composite particle 1 is made in the incomplete covering state, the cycle characteristics can be compatible with the initial battery capacity.

In the ALD method, the powder contained in a vacuum container repeatedly undergoes a step of supplying a precursor gas and a step of removing excess molecules due to purge alternately, and thereby, atomic layers can be layered layer after layer. In the deposition process, since a self-termination mechanism of the surface chemical reaction works, uniform layer controlling on a scale of a single atomic layer can be possible and the inorganic oxide layer 3 with excellent film quality can be formed.

When the surface covering composite particle 1 is in the incomplete covering state, lithium ions can transfer between the positive electrode active material particle 2 and an electrolyte via portions in which the surface of the positive electrode active material particle 2 is exposed, this not prohibited by the inorganic oxide layer 3. Accordingly, the surface covering composite particle 1 can maintain charge transfer resistance equivalent to the non-covering particle, and decrease in initial battery capacity caused by resistance elevation can be suppressed. On the other hand, when the surface covering composite particle 1 is in the complete covering state, although cycle characteristics can be improved, lithium ions pass through the covering layer to undergo intercalation and deintercalation in the positive electrode active material, this causing the resistance to elevate and the initial battery capacity to tend to decrease.

### [Variations]

Hereafter, variations of the first embodiment according to the present technology are described.

### (First Variation)

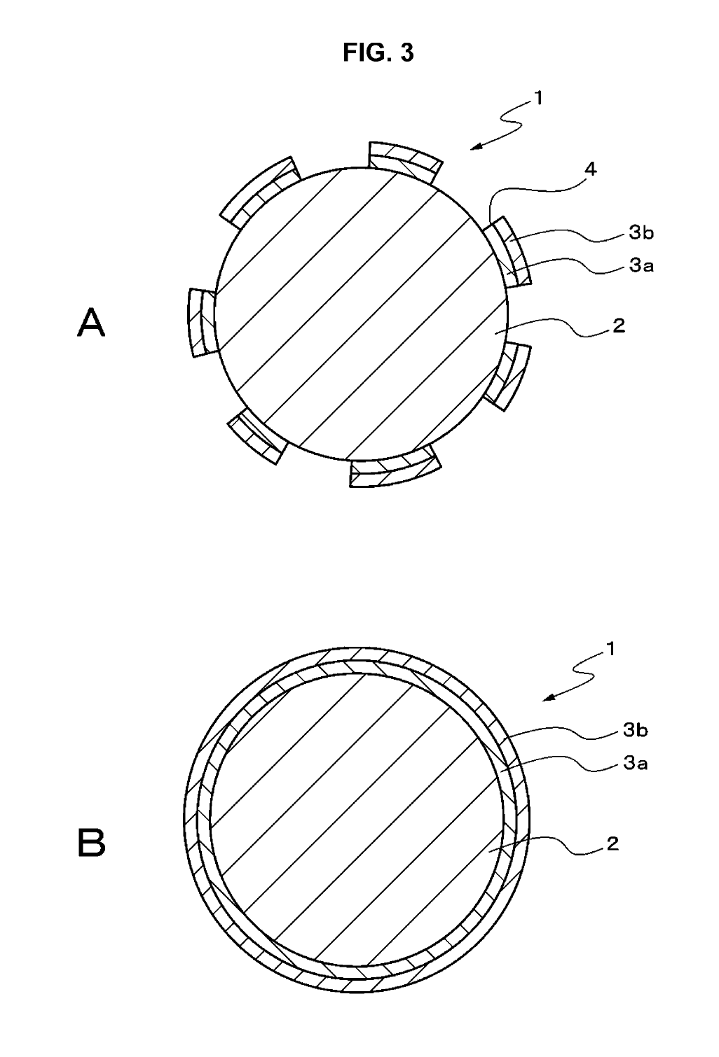

FIG. 3A is a cross-sectional view showing one exemplary configuration of a positive electrode active material according to a first variation. The positive electrode active material according to the first variation is different from that according to the first embodiment in that a first inorganic oxide layer 3a and a second inorganic oxide layer 3b are layered on the surface of the positive electrode active material particle 2. In addition, the layered number of inorganic oxide layers is not limited to that in this example but three or more layers as inorganic oxide layers may be layered on the surface of the positive electrode active material particle 2.

The first inorganic oxide layer 3a and the second inorganic oxide layer 3b are configured of, for example, inorganic oxides different from each other. For example, the first inorganic oxide layer 3a is configured of a first metal oxide such as aluminum oxide and the second inorganic oxide layer 3b is configured of a second metal oxide such as silicon oxide.

The inorganic oxide layer 3a and the second inorganic oxide layer 3b may be layers which are formed by formation methods different from each other. More specifically, one of the inorganic oxide layer 3a and the second inorganic oxide layer 3b may be a layer formed by the ALD method and the other may be a layer formed by a sol-gel method or a mechanochemical method. In the case where such a configuration is employed, the inorganic oxide layer 3a and the second inorganic oxide layer 3b may be configured of the identical material.

In FIG. 3A, an example in which part of the surface of the positive electrode active material particle 2 is exposed from the layered first inorganic oxide layer 3a and second inorganic oxide layer 3b is shown, whereas the configuration of the positive electrode active material particle 1 which is of a covering type is not limited to this example. As shown in FIG. 3B, a configuration in which the entire surface of the positive electrode active material particle is completely covered with the layered first inorganic oxide layer 3a and second inorganic oxide layer 3b may be employed. One of the layered first inorganic oxide layer 3a and second inorganic oxide layer 3b may be made in the complete covering state and the others in the incomplete covering state.

### (Second Variation)

In the above-mentioned first embodiment, an example of providing the metal oxide layer 3 as the covering layer on the surface of the positive electrode active material particle 2 is described, whereas the covering layer is not limited to this example. As the covering layer, for example, a metal nitride layer, a metal sulfide layer, a metal carbide layer, a metal fluoride layer or the like may be used.

### 2. Second Embodiment

### Configuration of Battery

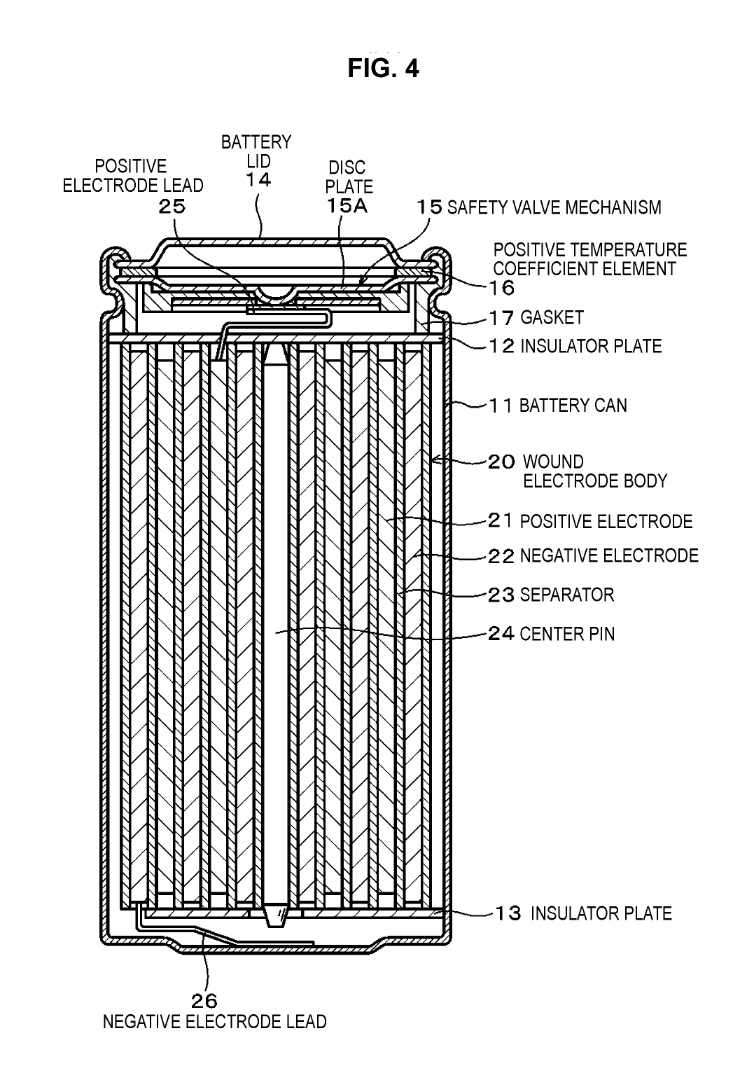

FIG. 4 is a cross-sectional view showing one exemplary configuration of a non-aqueous electrolyte secondary battery according to a second embodiment of the present technology. The non-aqueous electrolyte secondary battery is a so-called lithium ion secondary battery which has, for example, high output potential of a 5 V class and for which the capacity of its negative electrode is represented by a capacity component based on intercalation and deintercalation of lithium (Li) which is an electrode reaction substance. The non-aqueous electrolyte secondary battery is of a so-called cylinder type and has, inside a battery can 11 which is hollow and substantially columnar, a wound electrode body 20 obtained by winding a pair of a belt-shaped positive electrode 21 and a belt-shaped negative electrode 22 which are layered to interpose a separator 23. The battery can 11 is configured of iron (Fe) plated with nickel (Ni), one end part thereof is closed and the other end part is opened. Inside the battery can 11, an electrolyte solution is injected with which the separator 23 is impregnated. Moreover, a pair of insulator plates 12 and 13 are disposed perpendicular to the circumferential surface of winding to interpose the wound electrode body 20.

To the opening end part of the battery can 11, a battery lid 14, a safety valve mechanism 15 provided in the battery lid 14, and a positive temperature coefficient (PTC) element 16 are attached by swaging via an opening sealing gasket 17. Thereby, the inside of the battery can 11 is sealed. The battery lid 14 is configured, for example, of a material similar to that of the battery can 11. The safety valve mechanism 15 is electrically connected to the battery lid 14 and on the occasion that the inner pressure of the battery is not less than a certain value due to internal short, heating from the outside or the like, a disc plate 15A is configured to reverse so as to cut the electric connection between the battery lid 14 and the wound electrode body 20. The opening sealing gasket 17 is configured, for example, of insulative material and its surface is applied with asphalt.

Through the center of the wound electrode body 20, for example, a center pin 24 is inserted. A positive electrode lead 25 made of aluminum (Al) or the like is connected to a positive electrode 21 of the wound electrode body 20, and a negative electrode lead 26 made of nickel or the like is connected to a negative electrode 22. The positive electrode lead 25 is welded to the safety valve mechanism 15 to be electrically connected to the battery lid 14, and the negative electrode lead 26 is welded to the battery can 11 to be electrically connected thereto.

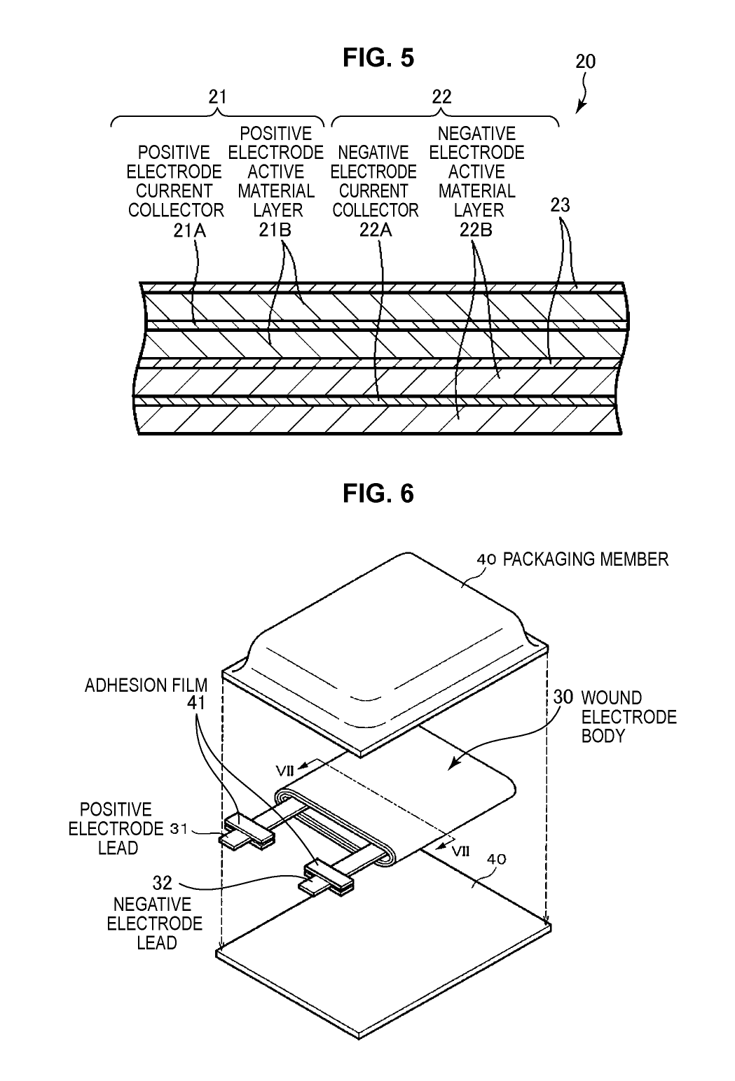

FIG. 5 is an enlarged cross-sectional view of a part of the wound electrode body 20 shown in FIG. 4. Hereafter, the positive electrode 21, the negative electrode 22, the separator 23 and the electrolyte solution which constitute the secondary battery are described sequentially with reference to FIG. 4.

### (Positive Electrode)

The positive electrode 21 has, for example, a structure in which positive electrode active material layers 21B are provided on the both sides of a positive electrode current collector 21A. In addition, the positive electrode active material layer 21B may be provided only on one side of the positive electrode current collector 21A, this not shown in any figure. The positive electrode current collector 21A is configured, for example, of a metal foil such as an aluminum foil. The positive electrode active material layer 21B is configured to contain, for example, one kind or two or more kinds of positive electrode active materials capable of intercalating and deintercalating lithium, and as necessary, to contain a conductive material such as graphite and a binder such as polyvinylidene fluoride.

As the positive electrode active materials capable of intercalating and deintercalating lithium, ones described in the above-mentioned first embodiment and variations thereof are used.

### (Negative Electrode)

The negative electrode 22 has, for example, a structure in which negative electrode active material layers 22B are provided on the both sides of a negative electrode current collector 22A. In addition, the negative electrode active material layer 22B may be provided only on one side of the negative electrode current collector 22A, this not shown in any figure. The negative electrode current collector 22A is configured, for example, of a metal foil such as a copper foil.

The negative electrode active material layer 22B is configured to contain one kind or two or more kinds of negative electrode materials capable of intercalating and deintercalating lithium as the negative electrode active material, and as necessary, configured to contain a binder similar to that of the positive electrode active material layer 21B.

In addition, in this secondary battery, an electrochemical equivalent of the negative electrode material capable of intercalate and deintercalating lithium is configured to be larger than an electrochemical equivalent of the positive electrode 21, and thus, configured not to allow lithium metal to deposit on the negative electrode 22 in the midway of charging.

Examples of the negative electrode material capable of intercalating and deintercalating lithium include, for example, carbon materials such as hardly graphitizable carbon, easily graphitizable carbon, graphite, thermally degraded carbons, cokes, glassy carbons, fired bodies of organic polymers, carbon fiber and activated carbon. Among these, the cokes include pitch cokes, needle cokes, petroleum cokes and the like. The fired bodies of organic polymers are carbons obtained by firing polymer materials such as phenol resin and furan resin at an appropriate temperature, and some of these are categorized as hardly graphitizable carbon or easily graphitizable carbon. Moreover, the polymer materials include polyacetylene, polypyrrole and the like. These carbon materials are preferable for which change in crystal structure arising in charging or discharging is exceedingly small and which can attain high charge/discharge capacity and good cycle characteristics. Particularly, graphite is preferable which has a large electrochemical equivalent and can attain high energy density. Moreover, hardly graphitizable carbon is preferable which can attain excellent characteristics. Furthermore, one which is low in charge/discharge potential, specifically, close to lithium metal in charge/discharge potential is preferable since it can easily realize high energy density of the battery.

Examples of the negative electrode material capable of intercalating and deintercalating lithium further include a material capable of intercalating and deintercalating lithium and containing at least one kind of metal elements and semi-metal elements as a constituent element. This is because a high energy density can be obtained with use of such a material. Such a material is preferably used together with carbon material because the high energy density and also excellent cycling characteristics can be obtained. The negative electrode material may be a simple substance, an alloy, or a compound of the metal element or the semi-metal element, or may contain, at least partly, a phase of one or more of the simple substance, alloy, or compound of the metal element or the semi-metal element. Note that in the present disclosure, the alloy includes a material formed with two or more kinds of metal elements and a material containing one or more kinds of metal elements and one or more kinds of semi-metal elements. Further, the alloy may contain a non-metal element. Examples of its texture include a solid solution, a eutectic (eutectic mixture), an intermetallic compound, and one in which two or more kinds thereof coexist.

Examples of the metal element or semi-metal element contained in this negative electrode material include magnesium (Mg), boron (B), aluminum (Al), gallium (Ga), indium (In), silicon (Si), germanium (Ge), tin (Sn), lead (Pb), bismuth (Bi), cadmium (Cd), silver (Ag), zinc (Zn), hafnium (Hf), zirconium (Zr), yttrium (Y), palladium (Pd), and platinum (Pt). These materials may be crystalline or amorphous.

It is preferable to use, as the negative electrode active material, for example, a material containing, as a constituent element, a metal element or a semi-metal element of 4B group in the short periodical table. It is more preferable to use a material containing at least one of silicon (Si) and tin (Sn) as a constituent element. This is because silicon (Si) and tin (Sn) each have a high capability of intercalating and deintercalating lithium (Li), so that a high energy density can be obtained.

Examples of the alloy of tin (Sn) include alloys containing, as a second constituent element other than tin (Sn), at least one selected from the group consisting of silicon (Si), nickel (Ni), copper (Cu), iron (Fe), cobalt (Co), manganese (Mn), zinc (Zn), indium (In), silver (Ag), titanium (Ti), germanium (Ge), bismuth (Bi), antimony (Sb), and chromium (Cr). Examples of the alloy of silicon (Si) include alloys containing, as a second constituent element other than silicon (Si), at least one selected from the group consisting of tin (Sn), nickel (Ni), copper (Cu), iron (Fe), cobalt (Co), manganese (Mn), zinc (Zn), indium (In), silver (Ag), titanium (Ti), germanium (Ge), bismuth (Bi), antimony (Sb), and chromium (Cr).

Examples of the compound of tin (Sn) or the compound of silicon (Si) include compounds containing oxygen (O) or carbon (C), which may contain any of the above-described second constituent elements in addition to tin (Sn) or silicon (Si).

Among them, as the negative electrode material, an SnCoC-containing material is preferable which contains cobalt (Co), tin (Sn), and carbon (C) as constituent elements, the content of carbon is higher than or equal to 9.9 mass % and lower than or equal to 29.7 mass %, and the ratio of cobalt in the total of tin (Sn) and cobalt (Co) is higher than or equal to 30 mass % and lower than or equal to 70 mass %. This is because the high energy density and excellent cycling characteristics can be obtained in these composition ranges.

The SnCoC-containing material may also contain another constituent element as necessary. For example, it is preferable to contain, as the other constituent element, silicon (Si), iron (Fe), nickel (Ni), chromium (Cr), indium (In), niobium (Nb), germanium (Ge), titanium (Ti), molybdenum (Mo), aluminum (Al), phosphorous (P), gallium (Ga), or bismuth (Bi), and two or more kinds of these elements may be contained. This is because the capacity characteristics or cycling characteristics can be further increased.

Note that the SnCoC-containing material has a phase containing tin (Sn), cobalt (Co), and carbon (C), and this phase preferably has a low crystalline structure or an amorphous structure. Further, in the SnCoC-containing material, at least a part of carbon (C), which is a constituent element, is preferably bound to a metal element or a semi-metal element that is another constituent element. This is because, when carbon (C) is bound to another element, aggregation or crystallization of tin (Sn) or the like, which is considered to cause a decrease in cycling characteristics, can be suppressed.

Further, examples of the negative electrode material capable of intercalating and deintercalating lithium include other metal materials and polymer compounds. Examples of the other metal compounds include oxides such as lithium titanate (Li4Ti5O12), manganese dioxide (MnO2), and vanadium oxide (V2O5, V6O13), sulfides such as nickel sulfide (NiS) and molybdenum sulfide (MoS2), and nitrides of lithium such as lithium nitride (Li3N); and examples of the polymer materials include polyacetylene, polyaniline, polypyrrole, and the like.

### (Separator)

The separator 23 separates the positive electrode 21 from the negative electrode 22 to prevent current short caused by contact of the both electrodes, and allows lithium ions to pass through. As the separator 23, for example, a porous film made of synthetic resin such as polytetrafluoroethylene, polypropylene and polyethylene, a single layer of a porous film made of ceramics, or a multi-layer of those can be used. Particularly, a porous film made of polyolefin is preferable for the separator 23. This is because it is excellent in short preventing effect and it can improve safety of the battery due to the shutdown effect. Moreover, as the separator 23, one which is obtained by forming a porous layer of resin such as polyvinylidene fluoride (PVdF) and polytetrafluoroethylene (PTFE) on a microporous film such as polyolefin may be used.

### (Electrolyte Solution)

The separator 23 is impregnated with an electrolyte solution which is electrolyte in a liquid form. The electrolyte solution contains a solvent and an electrolyte salt dissolved in the solvent.

As the solvent, a cyclic carbonate such as ethylene carbonate and propylene carbonate can be used and it is preferable to use one of ethylene carbonate and propylene carbonate, particularly, a mixture of both. This is because cycle characteristics can be improved.

In addition to these cyclic carbonates, as the solvent, an open-chain carbonate such as diethyl carbonate, dimethyl carbonate, ethyl methyl carbonate and methyl propyl carbonate is preferable to be used as a mixture with those. This is because high ion conductivity can be attained.

Furthermore, the solvent is preferable to contain 2,4-difluoroanisole and/or vinylene carbonate. This is because 2,4-difluoroanisole can improve discharge capacity and vinylene carbonate can improve cycle characteristics. Accordingly, mixing these to be used is preferable since the discharge capacity and the cycle characteristics can be improved.

Other than these, examples of the solvent include butylene carbonate, γ-butyrolactone, γ-valerolactone, 1,2-dimethoxyethane, tetrahydrofuran, 2-methyltetrahydrofuran, 1,3-dioxolane, 4-methyl-1,3-dioxolane, methyl acetate, methyl propionate, acetonitrile, glutaronitrile, adiponitrile, methoxyacetonitrile, 3-methoxypropionitrile, N,N-dimethylformamide, N-methylpyrrolidinone, N-methyloxazolidinone, N,N-dimethylimidazolidinone, nitromethane, nitroethane, sulfolane, dimethylsulfoxide, and trimethyl phosphate.

In addition, a compound obtained by substituting fluorine for at least part of hydrogen of any of these non-aqueous solvents is sometimes preferable since reversibility of the electrode reaction can be sometimes improved depending on kinds of electrodes used as a combination.

Examples of the electrolyte salt include, for example, lithium salts, one kind of them may be used solely and two or more kinds of them may be mixed to be used. Examples of the lithium salts include LiPF₆, LiBF₄, LiAsF6, LiClO₄, LiB(C₆H₅)₄, LiCH₃SO₃, LiCF₃SO₃, LiN(SO₂CF₃)₂, LiC(SO₂CF₃)₃, LiAlCl₄, LiSiF₆, LiCl, lithium difluoro[oxolato-O,O′]borate, lithium bisoxalatoborate, and LiBr. Above all, LiPF₆ is preferable to be able to attain high ion conductivity and improve cycle characteristics.

### [Manufacturing Method of Battery]

The following will show an example of a method for manufacturing the nonaqueous electrolyte secondary battery according the second embodiment of the present technology.

First, for example, a positive electrode mixture is prepared by mixing the positive electrode active material, a conductive material, and a binder, and a paste-form positive electrode mixture slurry is prepared by dispersing the positive electrode mixture into a solvent such as N-methyl-2-pyrrolidinone. Next, the positive electrode mixture slurry is applied on the positive electrode current collector 21A, the solvent is dried, and the dried mixture is compression molded with a rolling press machine or the like, so that the positive electrode active material layer 21B is formed and the positive electrode 21 is manufactured.

Further, for example, a negative electrode mixture is prepared by mixing a negative electrode active material and a binder, and a paste-form negative electrode mixture slurry is prepared by dispersing this negative electrode mixture in a solvent such as N-methyl-2-pyrrolidone. Next, the negative electrode mixture slurry is applied on the negative electrode current collector 22A, the solvent is dried, and the dried mixture is compression molded with a rolling press machine or the like, so that the negative electrode active material layer 22B is formed and the negative electrode 22 is manufactured.

Next, the positive electrode lead 25 is attached to the positive electrode current collector 21A by welding or the like, and the negative electrode lead 26 is attached to the negative electrode current collector 22A by welding or the like. Next, the positive electrode 21 and the negative electrode 22 are wound via the separator 23. Next, the tip part of the positive electrode lead 25 is welded to the safety valve mechanism 15, the tip part of the negative electrode lead 26 is welded to the battery can 11, and the wound positive electrode 21 and negative electrode 22 are interposed between the pair of insulator plates 12 and 13 and are contained inside the battery can 11. Next, after the positive electrode 21 and the negative electrode 22 are contained inside the battery can 11, the electrolyte solution is injected into the battery can 11 to impregnate the separator 23. Next, the battery lid 14, the safety valve mechanism 15 and the positive temperature coefficient element 16 are fixed to the opening end part of the battery can 11 by swaging via the opening sealing gasket 17. Thereby, the secondary battery shown in FIG. 4 is obtained.

In the non-aqueous electrolyte secondary battery according to the second embodiment, since the positive electrode 21 contains the above-mentioned positive electrode active material according to the first embodiment, cycle characteristics can be improved.

### 3. Third Embodiment

### Configuration of Battery

FIG. 6 is an exploded perspective view of one exemplary configuration of a non-aqueous electrolyte secondary battery according to a third embodiment of the present technology. The secondary battery is one in which a wound electrode body 30 to which a positive electrode lead 31 and a negative electrode lead 32 are attached is contained inside film-form packaging members 40, and is enabled to be small in dimensions and light in weight and to be thin.

Each of the positive electrode lead 31 and the negative electrode lead 32 is led out from the inside of the package member 40 toward the outside in the same direction, for example. The positive electrode lead 31 and the negative electrode lead 32 are each formed using, for example, a metal material such as aluminum, copper, nickel, or stainless steel, in a thin plate state or a network state.

Each of the packaging members 40 is configured, for example, of a rectangular aluminum laminate film obtained by pasting a nylon film, an aluminum foil and a polyethylene film in this order. Each of the packaging members 40 is disposed, for example, such that the polyethylene film side thereof faces the wound electrode body 30, and their outer edge parts adhere to each other by fusion or with an adhesive. Adhesion films 41 are inserted between the packaging members 40 and the positive electrode lead 31 and negative electrode lead 32 to prevent intrusion of the air. The adhesion film 41 is configured of a material having adherence with respect to the positive electrode lead 31 and the negative electrode lead 32, which material is, for example, polyolefin resin such as polyethylene, polypropylene, modified polyethelene and modified polypropylene.

Note that the metal layer of the package member 40 may also be formed using a laminated film having another lamination structure, or a polymer film such as polypropylene or a metal film, instead of the above-described aluminum laminated film.

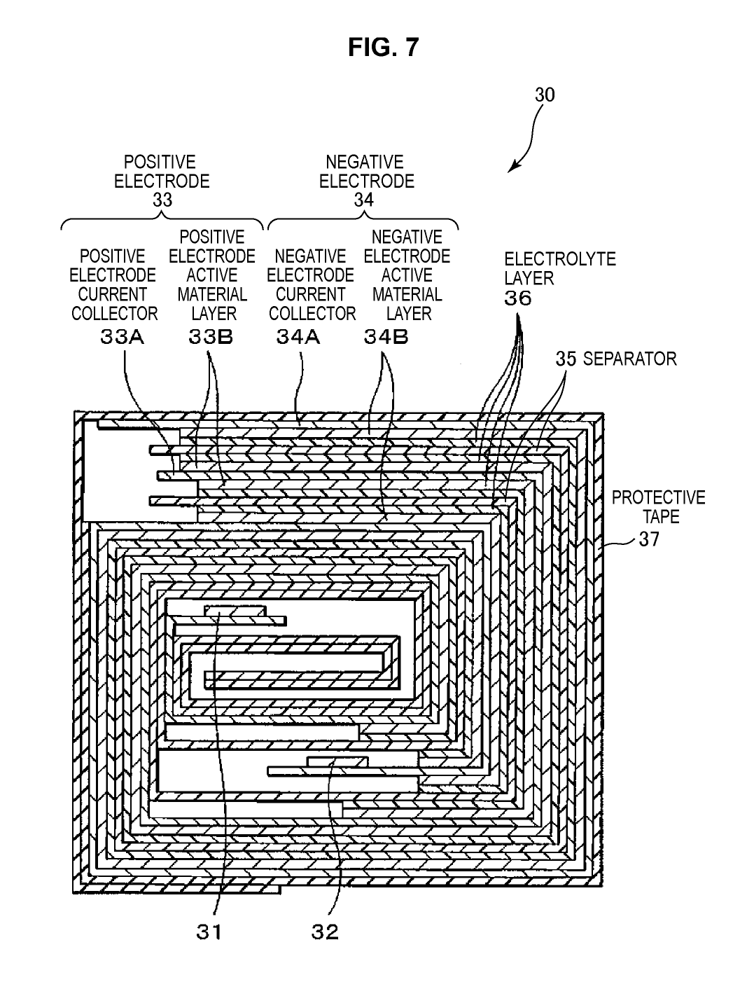

FIG. 7 shows a cross-sectional structure along an VII-VII line of the wound electrode body 30 shown in FIG. 6. This wound electrode body 30 is prepared by laminating a positive electrode 33 and a negative electrode 34 with a separator 35 and an electrolyte layer 36 interposed therebetween and winding the laminate, and an outermost peripheral portion thereof is protected by a protective tape 37.

The positive electrode 33 has a structure in which positive electrode active material layers 33B are provided on one side or both sides of the positive electrode current collector 33A. The negative electrode 34 has a structure in which negative electrode active material layers 34B are provided on one side or both sides of the negative electrode current collector 34A, and the negative electrode active material layer 34B is disposed so as to face the positive electrode active material layer 33B. The configurations of the positive electrode current collector 33A, the positive electrode active material layer 33B, the negative electrode current collector 34A, the negative electrode active material layer 34B and the separator 35 are similar to those of the positive electrode current collector 21A, the positive electrode active material layer 21B, the negative electrode current collector 22A, the negative electrode active material layer 22B and the separator 23 in the second embodiment, respectively.

The electrolyte layer 36 contains an electrolyte solution and a polymer compound which is a retention body retaining the electrolyte solution, and is in a so-called gel form. The gel-form electrolyte layer 36 is preferable to be able to attain high ion conductivity and prevent leakage in the battery. The composition of the electrolyte solution is similar to that of the secondary battery according to the second embodiment. Examples of the polymer compound include, for example, polyacrilonitrile, polyvinylidene fluoride, copolymer of polyvinylidene fluoride and polyhexafluoropropylene, polytetrafluoroethylene, polyhexafluoropropylene, polyethylene oxide, polypropylene oxide, polyphosphazene, polysiloxane, polyvinyl acetate, polyvinyl alcohol, polymethyl methacrylate, polyacrylic acid, polymethacrylic acid, a styrene-butadiene rubber, a nitrile-butadiene rubber, polystyrene and polycarbonate. Particularly, in view of electrochemical stability, polyacrilonitrile, polyvinylidene fluoride, polyhexafluoropropylene or polyethylene oxide is preferable.

### [Manufacturing Method of Battery]

The following will show an example of a method for manufacturing the nonaqueous electrolyte secondary battery according the third embodiment of the present technology.

A precursor solution including a solvent, an electrolyte salt, a polymer compound, and a mixed solvent is applied on surfaces of each of the positive electrode 33 and the negative electrode 34, and the mixed solvent is then volatilized to form the electrolyte layer 36. Subsequently, the positive electrode 33 and the negative electrode 34 each having the electrolyte layer 36 formed thereon are laminated with the separator 35 interposed therebetween to form a laminate, and then the laminate is wound in a longitudinal direction thereof and the protective tape 37 is adhered to an outermost peripheral portion to form the wound electrode body 30. Finally, for example, the wound electrode body 30 is interposed between the package members 40, and the outer periphery portions of the package members 40 are adhered to each other by means of heat fusion or the like, thereby enclosing the wound electrode body 30 therein. On that occasion, the contact film 41 is inserted between each of the positive electrode lead 31 and the negative electrode lead 32 and the package member 40. There is thus obtained a secondary battery shown in FIGS. 6 and 7.

Alternatively, the secondary battery may be manufactured as follows. First of all, in the above-described manner, the positive electrode 33 and the negative electrode 34 are formed, and the positive electrode lead 31 and the negative electrode lead 32 are attached to the positive electrode 33 and the negative electrode 34, respectively. After that, the positive electrode 33 and the negative electrode 34 are laminated with the separator 35 interposed therebetween, the laminate is wound, and the protective tape 37 is adhered to an outermost peripheral portion, thereby forming a wound body which is a precursor of the wound electrode body 30. Next, the wound body is interposed between the package members 40, the outer peripheral portions except for one side are adhered to each other by heat fusion to make a bag form, and the wound electrode body 30 is housed in the inside of the package member 40. Subsequently, an electrolyte composite including, a solvent, an electrolyte salt, a monomer which is a raw material of a polymer compound, a polymerization initiator, and another material such as a polymerization inhibitor as necessary is prepared and injected into the inside of the package member 40.

Next, the opening part of the packaging member 40 undergoes thermal fusion under a vacuum atmosphere to be sealed after the electrolyte composite is injected into the inside of the packaging member 40. Next, it is applied with heat such that the monomer is polymerized to be a polymer compound, formed into the gel-form electrolyte layer 36. As above, the secondary battery shown in FIG. 6 is obtained.

The actions and effects of the non-aqueous electrolyte secondary battery according to the third embodiment are similar to those of the non-aqueous electrolyte secondary battery according to the second embodiment.

### 4. Fourth Embodiment

### Example of Battery Pack

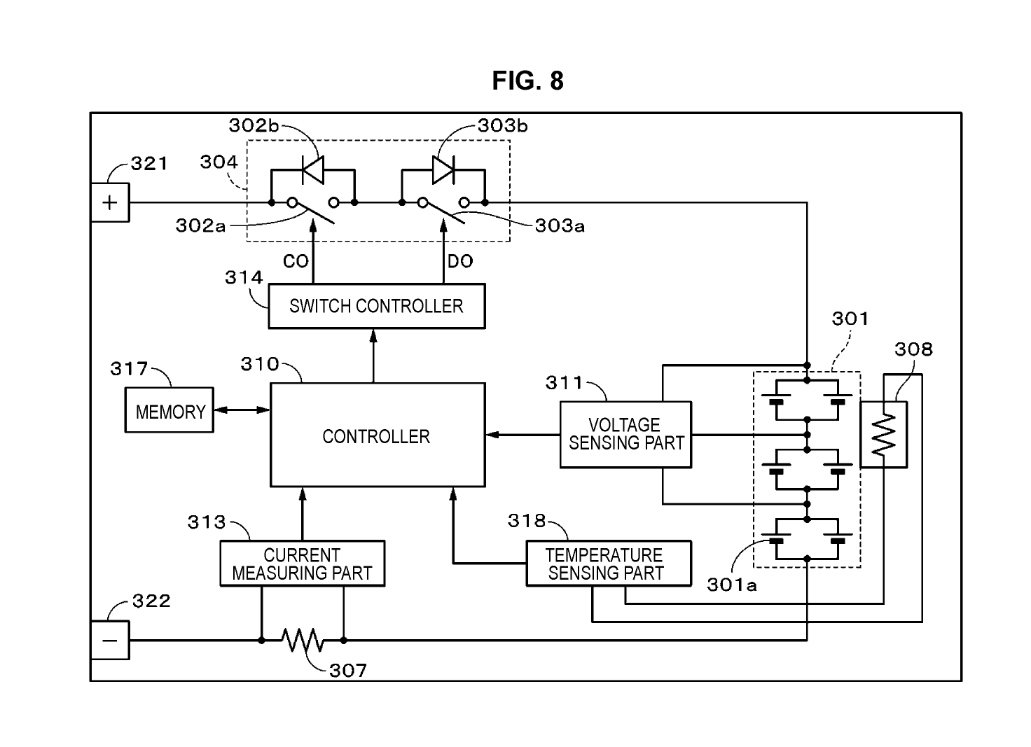

FIG. 8 is a block diagram showing a circuit configuration example in a case where the nonaqueous electrolyte secondary battery according an embodiment of the above-described present technology (hereinafter, referred to as the secondary battery). The battery pack includes an assembled battery 301, a package, a switch part 304 including a charge control switch 302a and a discharge control switch 303a, a current sensing resistor 307, a temperature sensing element 308, and a controller 310.

Further, the battery pack includes a positive electrode terminal 321 and a negative electrode terminal 322, and at the time of charge, the positive electrode terminal 321 and the negative electrode terminal 322 are connected to a positive electrode terminal and a negative electrode terminal of a battery charger, respectively, and charge is performed. Further, at the time of using an electronic device, the positive electrode terminal 321 and the negative electrode terminal 322 are connected to a positive electrode terminal and a negative electrode terminal of the electronic device, respectively, and discharge is performed.

The assembled battery 301 is formed by connecting a plurality of secondary batteries 301a in series and/or in parallel. Each of the secondary batteries 301a is the secondary battery according to an embodiment of the present technology. Note that although FIG. 8 shows an example in which six secondary batteries 301a are connected so as to have two parallel connections and three series connections (2P3S), any other connection can be adopted such as n parallel and m series (n and m are integers) connections.

The switch part 304 includes the charge control switch 302a, a diode 302b, the discharge control switch 303a, and a diode 303b, and is controlled by the controller 310. The diode 302b has a polarity that is reverse to charge current flowing in the direction from the positive electrode terminal 321 to the assembled battery 301 and forward to discharge current flowing in the direction from the negative electrode terminal 322 to the assembled battery 301. The diode 303b has a polarity that is forward to the charge current and reverse to the discharge current. Note that although an example is shown in which the switch part is provided on a plus side, the switch part 104 may be provided on a minus side.

The charge control switch 302a is turned off when the battery voltage is an overcharge detection voltage and is controlled by a charge/discharge controller so that charge current does not flow into a current path of the assembled battery 301. After the charge control switch is turned off, only discharge is possible via the diode 302b. Further, when overcurrent flows during charge, the charge control switch is turned off and controlled by the controller 310 so that charge current flowing in the current path of the assembled battery 301 is cut off.

The discharge control switch 303a is turned off when the battery voltage is an overdischarge detection voltage and is controlled by the controller 310 so that discharge current does not flow into the current path of the assembled battery 301. After the discharge control switch 303a is turned off, only charge is possible via the diode 303b. Further, when overcurrent flows during discharge, the discharge control switch 303a is turned off and controlled by the controller 310 so that discharge current flowing in the current path of the assembled battery 301 is cut off.

The temperature sensing element 308 is a thermistor for example, and is provided near the assembled battery 301, measures the temperature of the assembled battery 301, and supplies the measured temperature to the controller 310. A voltage sensing part 311 measures the voltage of the assembled battery 301 and of secondary battery 301a forming the assembled battery 301, A/D converts the measured voltage, and supplies the voltage to the controller 310. A current measuring part 313 measures current with the current sensing resistor 307, and supplies the measured current to the controller 310.

A switch controller 314 controls the charge control switch 302a and the discharge control switch 303a of the switch part 304, based on the voltage and current input from the voltage sensing part 311 and the current measuring part 313. When the voltage of any of the secondary batteries 301a is the overcharge detection voltage or lower or the overdischarge detection voltage or lower, or when overcurrent flows rapidly, the switch controller 314 transmits a control signal to the switch part 304 to prevent overcharge, overdischarge, and overcurrent charge/discharge.

Herein, when the secondary battery 301a is a lithium ion secondary battery, for example, the overcharge detection voltage is defined, for example, as 4.20 V±0.05 V and the overdischarge detection voltage is defined, for example, as 2.4 V±0.1 V.

As a charge/discharge switch, for example, a semiconductor switch such as a MOSFET can be used. In this case, a parasitic diode of the MOSFET serves as the diodes 302b and 303b. In a case where a p-channel FET is used as the charge/discharge switch, the switch controller 314 supplies a control signal DO and a control signal CO to a gate of the charge control switch 302a and a gate of the discharge control switch 303a, respectively. In the case of the p-channel type, the charge control switch 302a and the discharge control switch 303a are turned on at a gate potential which is lower than a source potential by a predetermined value or more. That is, in normal charge and discharge operations, the charge control switch 302a and the discharge control switch 303a are made to be in an ON state by setting the control signals CO and DO to low levels.

Further, when performing overcharge or overdischarge, for example, the charge control switch 302a and the discharge control switch 303a are made to be in an OFF state by setting the control signals CO and DO to high levels.

A memory 317 is formed of a RAM or ROM, and is formed of an erasable programmable read only memory (EPROM), which is a volatile memory, for example. The memory 317 stores, in advance, the value calculated in the controller 310, the internal resistance value of the battery in an initial state of each of the secondary batteries 301a measured at a stage in a manufacturing process, and the like, which are rewritable as necessary. Further, by storing a full charge capacity of the secondary battery 301a, the memory 317 can calculate the remaining capacity together with the controller 310, for example.

A temperature sensing part 318 measures the temperature with use of the temperature sensing element 308, controls charge/discharge at the time of abnormal heat generation, and corrects the calculation of the remaining capacity.

### 5. Fifth Embodiment

The above-mentioned non-aqueous electrolyte secondary battery and a battery pack having the non-aqueous electrolyte secondary battery can be mounted on a device, such as an electronic device, an electric vehicle, and a power storage device, or can be used to supply electric power to such device.

Examples of the electronic device include a laptop personal computer, a PDA (mobile information device), a mobile phone, a cordless extension, a video movie, a digital still camera, an e-book reader, an electronic dictionary, a music player, a radio, a headphone, a game machine, a navigation system, a memory card, a pacemaker, a hearing aid, an electric tool, an electric razor, a refrigerator, an air conditioner, a television set, a stereo, a water heater, a microwave, a dishwasher, a washer, a drier, a lighting device, a toy, a medical device, a robot, a road conditioner, a traffic light, and the like.

Further, examples of the electric vehicle include a railway train, a golf cart, an electric cart, an electric car (including a hybrid car), and the like. Each battery and the battery pack 100 described in any of the second to fifth embodiments can be used as a power source for driving these vehicles or as a supplementary power source.

Examples of the power storage device include a power source for power storage for buildings such as houses or for power generation equipment, and the like.

From the above application examples, the following will show a specific example of a power storage system using the power storage device using the nonaqueous electrolyte secondary battery according an embodiment of the above-described present technology.

This power storage system can have the following structure for example. A first power storage system is a power storage system in which the power storage device is charged with a power generation device which generates power from renewable energy. A second power storage system is a power storage system which includes the power storage device and supplies power to an electronic device connected to the power storage device. A third power storage system is an electronic device which is supplied with power from the power storage device. These power storage systems are each implemented as a system to supply power efficiently in association with an external power supply network.

Further, a fourth power storage system is an electric vehicle including a conversion device which converts power supplied from the power storage device to driving power of a vehicle, and a control device which performs information processing about vehicle control based on information about the power storage device. A fifth power storage system is a power system including a power information transmitting/receiving part which transmits/receives signals to/from other devices via a network, and controls charge/discharge of the power storage device based on information received by the transmitting/receiving part. A sixth power storage system is a power system which enables power supply from the power storage device and power supply to the power storage device from a power generation device or a power network. The following will show the power storage system.

(Home Power Storage System as Application Example)

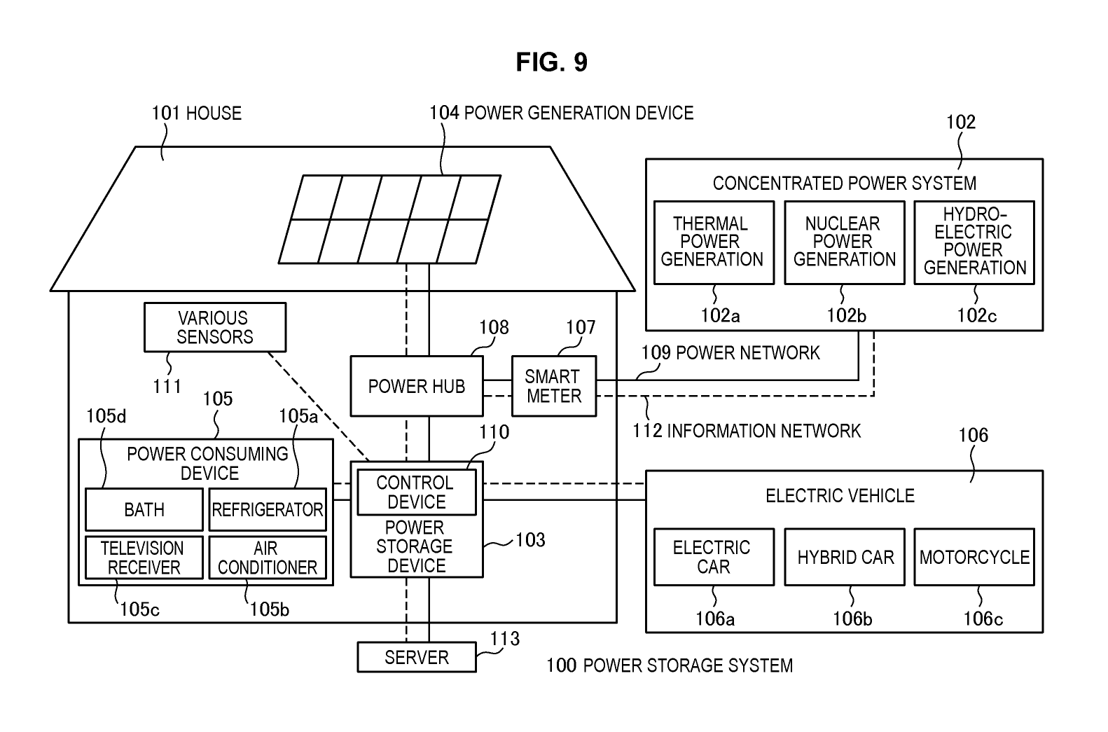

An example in which the power storage device using the nonaqueous electrolyte secondary battery according to an embodiment of the present technology is used for a home power storage system will be described with reference to FIG. 9. For example, in a power storage system 100 for a house 101, power is supplied to the power storage device 103 from a concentrated power system 102 including thermal power generation 102a, nuclear power generation 102b, hydroelectric power generation 102c, and the like, via a power network 109, an information network 112, a smart meter 107, a power hub 108, and the like. Further, power is supplied to the power storage device 103 from an independent power source such as a home power generation device 104. Power supplied to the power storage device 103 is stored, and power to be used in the house 101 is fed with use of the power storage device 103. The same power storage system can be used not only in the house 101 but also in a building.

The house 101 is provided with the home power generation device 104, a power consumption device 105, the power storage device 103, a control device 110 which controls each device, the smart meter 107, and sensors 111 which acquires various pieces of information. The devices are connected to each other by the power network 109 and the information network 112. As the power generation device 104, a solar cell, a fuel cell, or the like is used, and generated power is supplied to the power consumption device 105 and/or the power storage device 103. Examples of the power consumption device 105 include a refrigerator 105a, an air conditioner 105b, a television receiver 105c, a bath 105d, and the like. Examples of the power consumption device 105 further include an electric vehicle 106 such as an electric car 106a, a hybrid car 106b, or a motorcycle 106c.

For the power storage device 103, the nonaqueous electrolyte secondary battery according an embodiment of the present technology is used. The nonaqueous electrolyte secondary battery according an embodiment of the present technology may be formed of the above-described lithium ion secondary battery for example.

Functions of the smart meter 107 include measuring the used amount of commercial power and transmitting the measured used amount to a power company. The power network 109 may be any one or more of DC power supply, AC power supply, and contactless power supply.

Examples of the various sensors 111 include a motion sensor, an illumination sensor, an object detecting sensor, a power consumption sensor, a vibration sensor, a touch sensor, a temperature sensor, an infrared sensor, and the like. Information acquired by the various sensors 111 is transmitted to the control device 110. With the information from the sensors 111, weather conditions, people conditions, and the like are caught, and the power consumption device 105 is automatically controlled so as to make the energy consumption minimum. Further, the control device 110 can transmit information about the house 101 to an external power company via the Internet, for example.

The power hub 108 performs processes such as branching off power lines and DC/AC conversion. Examples of communication schemes of the information network 112 connected to the control device 110 include a method using a communication interface such as UART (Universal Asynchronous Receiver/Transceiver), and a method using a sensor network according to a wireless communication standard such as Bluetooth (registered trademark), ZigBee, or Wi-Fi. A Bluetooth (registered trademark) scheme can be used for multimedia communication, and one-to-many connection communication can be performed. ZigBee uses a physical layer of IEEE (Institute of Electrical and Electronics Engineers) 802.15.4. IEEE802.15.4 is the name of a near-field wireless network standard called PAN (Personal Area Network) or W (Wireless) PAN.

The control device 110 is connected to an external server 113. The server 113 may be managed by any of the house 101, an electric company, and a service provider. Examples of information transmitted and received by the server 113 include power consumption information, life pattern information, electric fee, weather information, natural disaster information, and information about power trade. Such information may be transmitted and received by the power consumption device (e.g., the television receiver) in the house, or may be transmitted and received by a device (e.g., a mobile phone) outside the house. Further, such information may be displayed on a device having a display function, such as the television receiver, the mobile phone, or the PDA (Personal Digital Assistant).

The control device 110 controlling each part is configured with a CPU (Central Processing Unit), a RAM (Random Access Memory), a ROM (Read Only Memory), and the like, and is stored in the power storage device 103 in this example. The control device 110 is connected to the power storage device 103, the home power generation device 104, the power consumption device 105, the various sensors 111, and the server 113 via the information network 112, and has a function of adjusting the used amount of commercial power and the power generation amount, for example. Note that the control device 110 may further have a function of performing power trade in the power market.

As described above, power generated by not only the concentrated power system 102 such as the thermal power generation 102a, the nuclear power generation 102b, and the hydroelectric power generation 102c, but also the home power generation device 104 (solar power generation or wind power generation) can be stored in the power storage device 103. Therefore, even when the power generated by the home power generation device 104 varies, the amount of power supplied to the outside can be constant, or only necessary discharge can be controlled. For example, power generated by the solar power generation can be stored in the power storage device 103 and also inexpensive power at midnight can be stored in the power storage device 103 during nighttime, so that power stored in the power storage device 103 can be discharged and used when the power fee is expensive during daytime.

Note that although this example shows the control device 110 housed in the inside of the power storage device 103, the control device 110 may be housed in the inside of the smart meter 107 or configured independently. Further, the power storage system 100 may be used for a plurality of houses in a multiple dwelling house or a plurality of separate houses.

### (Power Storage System in Vehicle as Application Example)

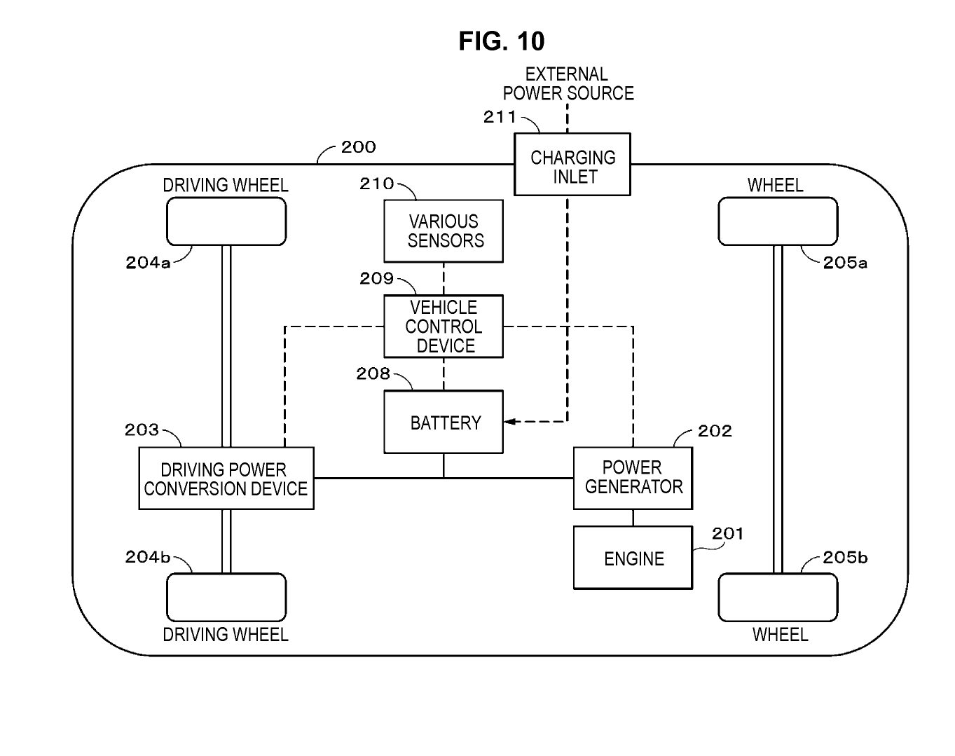

An example in which an embodiment of the present disclosure is applied to a power storage system for vehicles will be described with reference to FIG. 10. FIG. 10 schematically shows an example of a structure of a hybrid vehicle employing a series hybrid system to which an embodiment of the present disclosure is applied. The series hybrid system is a car which runs with a driving power conversion device using power generated by a power generator driven by an engine or power obtained by storing the power in a battery.

A hybrid vehicle 200 incorporates an engine 201, a power generator 202, a driving power conversion device 203, driving wheels 204a and 204b, wheels 205a and 205b, a battery 208, a vehicle control device 209, various sensors 210, and a charging inlet 211. For the battery 208, the nonaqueous electrolyte secondary battery according an embodiment of the above-described present technology is used.

The hybrid vehicle 200 runs by using the driving power conversion device 203 as a power source. One of examples of the driving power conversion device 203 is a motor. Power in the battery 208 drives the driving power conversion device 203, and the rotating power of the driving power conversion device 203 is transmitted to the driving wheels 204a and 204b. Note that by using DC/AC conversion or AC/DC conversion in a necessary portion, an alternate current motor or a direct current motor can be used for the driving power conversion device 203. The various sensors 210 control the number of engine rotation via the vehicle control device 209 and controls the aperture of an unshown throttle valve (throttle aperture). The various sensors 210 include a speed sensor, an acceleration sensor, a sensor of the number of engine rotation, and the like.

The rotating power of the engine 201 is transmitted to the power generator 202, and power generated by the power generator 202 with the rotating power can be stored in the battery 208.

When the hybrid vehicle 200 reduces the speed with an unshown brake mechanism, the resisting power at the time of the speed reduction is added to the driving power conversion device 203 as the rotating power, and regenerative power generated by the driving power conversion device 203 with this rotating power is stored in the battery 208.

The battery 208 can be connected to an external power source of the hybrid vehicle 200, and accordingly, power can be supplied from the external power source by using the charging inlet 211 as an input inlet, and the received power can be stored.

Although not shown, an information processing device which performs information processing about vehicle control based on information about the secondary battery may be provided. Examples of such an information processing device include an information processing device which displays the remaining battery based on information about the remaining battery.

Note that the above description is made by taking an example of the series hybrid car which runs with a motor using power generated by a power generator driven by an engine or power obtained by storing the power in a battery. However, an embodiment of the present disclosure can also be applied effectively to a parallel hybrid car which uses the output of an engine and a motor as the driving power source and switches three modes as appropriate: driving with the engine only; driving with the motor only; and driving with the engine and the motor. Further, an embodiment of the present disclosure can also be applied effectively to a so-called electric vehicle which runs by being driven with a driving motor only, without an engine.

The following examples will show embodiments of the present disclosure in detail. Note that structures of the embodiments of the present disclosure are not limited to the following examples.

The average thickness of an Al₂O₃ layer (covering layer: inorganic oxide layer) of a covered LiCoO₂ particle (surface covering composite particle) and the average coverage ratio of the covered LiCoO₂ particle in the examples was obtained as follows.

### (Average Thickness)

The average thickness Dn of the Al₂O₃ layer constituted of n monolayers was obtained using the following expression.

Dn=D1×n

D1: average thickness of the Al₂O₃ layer constituted of one monolayer

n: cycle number of the ALD process

In addition, the average thickness D1 of the Al₂O₃ layer constituted of one monolayer was obtained as follows. First, the ALD process was repeated by 100 cycles to form the Al₂O₃ layer constituted of 100 monolayers on the surface of the LiCoO₂ particle (positive electrode active material particle), and thereby, powder of a positive electrode active material constituted of the covered LiCoO₂ particles was obtained. Next, a cross-sectional TEM image of the covered LiCoO₂ particles contained in the powder of the positive electrode active material was acquired and a thickness of the Al₂O₃ layer was measured from the TEM image. Acquisitions of cross-sectional TEM images as mentioned above and measurements of the thicknesses from the TEM images were performed for 10 covered LiCoO₂ particles selected at random from the powder of the positive electrode active material, and the thicknesses of d₁, d₂, . . . , d₁₀ of the Al₂O₃ layer were obtained. Next, the obtained thicknesses d₁, d₂, . . . , d₁₀ underwent simple averaging (arithmetic mean) to obtain the average thickness D of the Al₂O₃ layer constituted of 100 monolayers. Next, the thickness D1 of the Al₂O₃ layer constituted of one monolayer was calculated by dividing the average thickness D of the Al₂O₃ layer by the number of deposition of monolayers which is “100”.

### (Average Coverage Ratio)

The average coverage ratio of the covered LiCoO₂ particle was obtained by the following expression.

Average coverage ratio[%]=(actual mass of the Al₂O₃ layer/(mass of the Al₂O₃ in the coverage ratio being 100%))×100=(x/(A(M−x)·n·p))×10⁵

M [g]: Mass of the powder of the covered LiCoO₂ particle powder used for ICP-AES analysis

x [g]: Actual mass of the Al₂O₃ layer in the covered LiCoO₂ particle powder used for ICP-AES analysis

A [m²/g]: Specific surface area of the LiCoO₂ particle

n [nm]: Average thickness of the Al₂O₃ layer obtained by cross-sectional TEM observation

ρ [g/cm³]: Density of the Al₂O₃ layer evaluated using XRR

### (Actual Weight x of Al₂O₃ Layer)

Specifically, the actual weight x of the Al₂O₃ layer was obtained as follows. First, mass M of the covered LiCoO₂ particle powder was weighed. Next, the covered LiCoO₂ particle powder was dissolved in an acid solution, the solution was analyzed by ICP-AES and a mass ratio A:B [wt. %] between the LiCoO₂ particle which is the core particle and the Al₂O₃ layer was quantified.

Next, the actual mass of the Al₂O₃ layer was calculated by the following expression.

Actual mass of the Al₂O₃ layer [g]=(mass M of the covered LiCoO₂ powder)×(mass ratio B of the Al₂O₃ layer)

### (Specific Surface Area A of LiCoO₂ Particle)

The specific surface area of the LiCoO₂ particle was obtained by the BET method (Brunauer-Emmett-Teller method). In addition, when the average thickness of the Al₂O₃ layer is exceedingly thin, for example, approximately 0.2 nm to 5 nm, the specific surface areas of the LiCoO₂ particle and the covered LiCoO₂ particle obtained by the BET method can be regarded as being substantially equal to each other.

### (Average Thickness n of Al₂O₃ Layer)

Specifically, the average thickness of the Al₂O₃ layer was obtained as follows. First, the ALD process was repeated by 100 cycles to form the Al₂O₃ layer constituted of 100 monolayers on the surface of the LiCoO₂ particle (positive electrode active material particle), and thereby, the powder of the positive electrode active material constituted of the covered LiCoO₂ particles was obtained. Next, a cross-sectional TEM image of the covered LiCoO₂ particles contained in the positive electrode active material powder was acquired and the thickness of the Al₂O₃ layer from the TEM image. Acquisitions of cross-sectional TEM images as mentioned above and measurements of the thicknesses from the TEM images were performed for 10 covered LiCoO₂ particles selected at random from the powder of the positive electrode active material, and the thicknesses d₁, d₂, . . . , d₁₀ of the Al₂O₃ layer were obtained. Next, the obtained thicknesses d₁, d₂, . . . , d₁₀ underwent simple averaging (arithmetic mean) to obtain the average thickness D of the Al₂O₃ layer constituted of 100 monolayers.

### (Density ρ of Al₂O₃ Layer)

Specifically, the density ρ of the Al₂O₃ layer was obtained as follows. First, the ALD process was repeated by 100 cycles to form the Al₂O₃ layer constituted of 100 monolayers on the surface of a silicon wafer. Next, the density of the Al₂O₃ layer was obtained by XRR. In addition, the deposition conditions (deposition temperature, deposition pressure, reaction gas amount with respect to the specific surface area of the deposition target) of the Al₂O₃ layers formed on the silicon wafer surface and the LiCoO₂ particle surface are identical with each other, the densities of the Al₂O₃ layer formed on the both surfaces can be regarded as being equal to each other.

Measurement conditions of XRR are shown as follows.

Apparatus: D8 DISCOVER μHR/TXS, Bruker AXS

X-ray source: Cu-Kα, 45 kV-20 mA

Light source size: 0.1×1 mm² (point focusing)

Entrance slit: 0.05 mm vertical slit+1×1 mm² cross slit

Detector slit: 0.1 mm+0.1 mm vertical double slit

Detector: scintillation counter

Scanning: θ-2θ interlocking mode, 0.2° to 2.0°, 0.002°□ of step, 1 sec of accumulation time

Examples of the present technology are described in the following order.

1. Relationship between Average Thickness of Inorganic Oxide Layer and Initial Capacity
2. Relationship between Average Coverage Ratio and Capacity Maintaining Ratio
3. Relationship between Average Coverage Ratio and Initial Capacity

### <1. Relationship Between Average Thickness of Inorganic Oxide Layer and Initial Capacity>

### Example 1-1

Powder of LiCoO₂ particles (Brand Name: Cellseed C-10N, Nippon Chemical Industrial) was prepared as a positive electrode active material. Next, the prepared powder was contained in the deposition chamber of the ALD apparatus. Next, the ALD process was repeated twice to form Al₂O₃ layers each of which was constituted of 2 monolayers on the LiCoO₂ particles, and thereby, the powder of the positive electrode active material which powder was constituted of the covered LiCoO₂ particles was obtained. As the gas of an oxygen source (first precursor) in the ALD process, steam was used, and as the gas of a metal source (second precursor), the gas of trimethyl aluminum (TMA) was used. The average thickness of the Al₂O₃ layer constituted of 2 monolayers was 0.2 nm. By changing the degree of aggregation of the LiCoO₂ particle powder (coordination number of the powder) in the deposition, the average coverage ratio of the covered LiCoO₂ particle powder was made 92%.

Using the obtained powder of the positive electrode active material as above, a non-aqueous electrolyte secondary battery of a coin type (hereinafter referred to as “coin cell”) was produced and the cycle characteristics of the battery (discharge capacity maintaining ratio).

First, 90 wt. % of the above-mentioned positive electrode active material and 5 wt. % of carbon black (conductive material) and 5 wt. % of polyvinylidene fluoride (binder) were mixed and tempered with an appropriate amount of N-methyl-2-pyrrolidone (NMP) and dried at 100° C. to obtain positive electrode mixture powder.

Next, the mixture powder was fixed to an aluminum mesh of Φ15 mm by pressing so as to obtain the positive electrode.

Next, as the negative electrode, a Li metal foil obtained by stamping-out into a disc from with a predetermined dimension was prepared. Next, as the separator, a microporous film made of polyethylene and having a thickness of 25 μm was prepared. Next, in a solvent obtained by mixing ethylene carbonate (EC) and dimethyl carbonate (DMC) in a mass ratio of 1:1, LiPF₆ as the electrolyte salt was dissolved to be at a concentration of 1 mol/kg to prepare the non-aqueous electrolyte solution.

Next, the produced positive electrode and negative electrode were layered via the microporous film to be a layered body, and along with the layered body, the non-aqueous electrolyte solution was contained inside a package cup and a package can and swaged via a gasket. Thereby, the coin cell of 2016 size (dimensions of 20 mm of diameter and 1.6 mm of height) was obtained.

### Example 1-2

A coin cell was obtained similarly to Example 1-1 except that the ALD process was repeated 6 times to form the Al₂O₃ layer constituted of 6 monolayers on the surface of the LiCoO₂ particle. In addition, the average thickness of the Al₂O₃ layer constituted of 6 monolayers was 0.6 nm

### Example 1-3

A coin cell was obtained similarly to Example 1-1 except that the ALD process was repeated 10 times to form the Al₂O₃ layer constituted of 10 monolayers on the surface of the LiCoO₂ particle. In addition, the average thickness of the Al₂O₃ layer constituted of 10 monolayers was 1 nm.

### Example 1-4

A coin cell was obtained similarly to Example 1-1 except that the ALD process was repeated 20 times to form the Al₂O₃ layer constituted of 20 monolayers on the surface of the LiCoO₂ particle. In addition, the average thickness of the Al₂O₃ layer constituted of 20 monolayers was 2 nm.

### Example 1-5

A coin cell was obtained similarly to Example 1-1 except that the ALD process was repeated 50 times to form the Al₂O₃ layer constituted of 50 monolayers on the surface of the LiCoO₂ particle. In addition, the average thickness of the Al₂O₃ layer constituted of 50 monolayers was 5 nm

### Comparative Example 1-1

A coin cell was obtained similarly to Example 1-1 except that the ALD process was omitted and the LiCoO₂ particle not covered with Al₂O₃ layer was used as the positive electrode active material.

### Comparative Example 1-2

A coin cell was obtained similarly to Example 1-1 except that the ALD process was repeated 70 times to form the Al₂O₃ layer constituted of 70 monolayers on the surface of the LiCoO₂ particle. In addition, the average thickness of the Al₂O₃ layer constituted of 70 monolayers was 7 nm

### Comparative Example 1-3

A coin cell was obtained similarly to Example 1-1 except that the ALD process was repeated 100 times to form the Al₂O₃ layer constituted of 100 monolayers on the surface of the LiCoO₂ particle. In addition, the average thickness of the Al₂O₃ layer constituted of 100 monolayers was 10 nm

### (Initial Capacity)

The initial capacities of the coin cells obtained as mentioned above were obtained as follows. First, constant current charge was performed at a constant current corresponding to 0.1 C until the battery voltage reached 4.5 V. In addition, the current value corresponding to 0.1 C was calculated, a theoretical specific capacity of the LiCoO₂ in charging at 4.5 V being 192 mAh/g. Next, constant current discharge was performed at the constant current corresponding to 0.1 C until the voltage reached 3.3 V to obtain the initial capacity (initial discharge capacity) [mAh]. Next, using this initial capacity [mAh], the initial capacity [mAh/g] was obtained per unit mass which was calculated by excluding the mass of the aluminum mesh, the conductive material and the binder from the mass of the positive electrode. The discharge herein means insertion reaction of lithium into the positive electrode active material. In addition, “1 C” is a current value at which the rated capacity of the battery undergoes constant current discharge for 1 hour. In addition, “0.1 C” is a current value at which the rated capacity of the battery undergoes the discharge for 10 hours.

The initial capacities obtained as mentioned above were evaluated on the basis of the following criteria.

Excellent: initial capacity obtained substantially equivalent to that of the coin cell of Comparative Example 1-1

Good: initial capacity being low compared with that of the coin cell of Comparative Example 1-1 and having the rate of decrease within 25%

Poor: initial capacity being low compared with that of the coin cell of Comparative Example 1-1 and having the rate of decrease above 25%

Herein, the rate of decrease in initial capacity was a rate of decrease based on the initial capacity in Comparative Example 1-1, and specifically, was calculated by the following expression.

Rate of decrease in initial capacity[%]=((initial capacity of the coin cell in each example)/(initial capacity of the coin cell in Comparative Example 1-1))×100

### (Results)

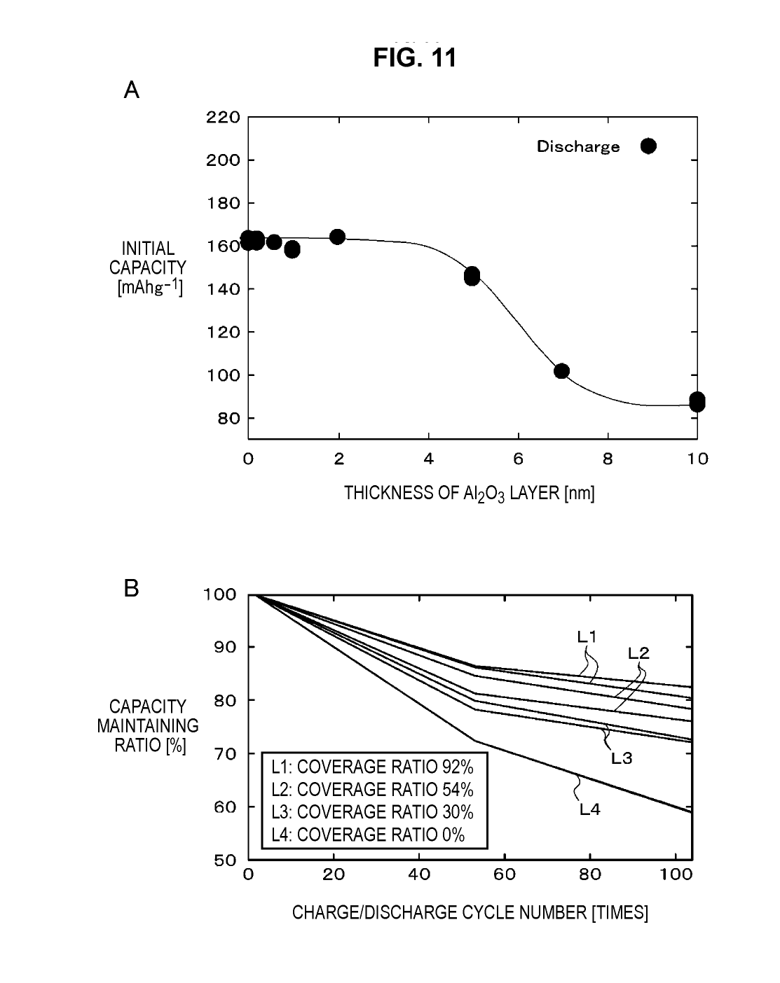

FIG. 11A shows relationship between thicknesses of the inorganic oxide layer and initial capacities regarding the coin cells in Examples 1-1 to 1-5 and Comparative Examples 1-1 to 1-3. In addition, in FIG. 11A, two coin cells for each of Examples 1-1 to 1-5 and Comparative Example 1-1 to 1-3 were prepared and the results of the initial capacities being obtained are shown. Table 1 presents the evaluation results of the coin cells in Examples 1-1 to 1-5 and Comparative Examples 1-1 to 1-3.

TABLE 1

| | Cycle Number | Average | Average | Evaluation of |
|---|---|---|---|---|
| | of ALD | Thickness | Coverage | Initial |
| | processes [Times] | [nm] | Ratio [%] | Capacity |
| Example 1-1 | 2 | 0.2 | 92 | — |
| Example 1-2 | 6 | 0.6 | | Excellent |
| Example 1-3 | 10 | 1.0 | | Excellent |
| Example 1-4 | 20 | 2.0 | | Excellent |
| Example 1-5 | 50 | 5.0 | | Good |
| Comparative | 0 | 0.0 | | — |
| Example 1-1 | | | | |
| Comparative | 70 | 7.0 | | Poor |
| Example 1-2 | | | | |
| Comparative | 100 | 10.0 | | Poor |
| Example 1-3 | | | | |

The followings were apparent from Table 1 and FIG. 11A. Excellent initial capacity was maintained with almost no change in initial capacity within a range of the cycle number of the ALD processes being 2 times or more and 20 times or less compared with the case of the cycle number of the ALD processes being 0 times. Although the initial capacity tended to decrease slightly within a range of the cycle number of the ALD processes exceeding 20 times and 50 times or less compared with the case of the cycle number of the ALD processes being 0 times, the rate of decrease was within 25%. The initial capacity tended largely to decrease within a range of the cycle number of ALD processes exceeding 50 times compared with the case of the cycle number of the ALD processes being 0 times, and the rate of decrease in initial capacity largely exceeded 25% at the stage of the cycle number reaching 70 times. Accordingly, in view of suppressing decrease in initial capacity caused by formation of the inorganic oxide layer, the cycle number of the ALD processes was to fall preferably within the range of 2 times or more and 50 times or less, and still preferably within the range of 2 times or more and 20 times or less. From the above-mentioned point of view, the average thickness of the inorganic oxide layer was to fall preferably 0.2 nm or more and 5.0 nm or less, and still preferably 0.2 nm or more and 2.0 nm or less.

### <2. Relationship Between Average Coverage Ratio and Capacity Maintaining Ratio>

### Example 2-1

A coin cell was obtained similarly to Example 1-3 except that the average coverage ratio of covered LiCoO₂ particle was set to 30% by adjusting the degree of aggregation of the LiCoO₂ particle powder contained in the deposition chamber of the ALD apparatus.

### Example 2-2

A coin cell was obtained similarly to Example 2-1 except that the average coverage ratio of covered LiCoO₂ particle was set to 54% by adjusting the degree of aggregation of the LiCoO₂ particle powder contained in the deposition chamber of the ALD apparatus.

### Example 2-3

A coin cell was obtained similarly to Example 2-1 except that the average coverage ratio of covered LiCoO₂ particle was set to 92% by adjusting the degree of aggregation of the LiCoO₂ particle powder contained in the deposition chamber of the ALD apparatus.

### Comparative Example 2-1

A coin cell was obtained similarly to Example 2-1 except that the ALD process was omitted and the LiCoO₂ particle not covered with Al₂O₃ layer was used as the positive electrode active material.

### (Capacity Maintaining Ratio)

The capacity maintaining ratios of the coin cells obtained as mentioned above were evaluated as follows. First, constant current charge was performed at a constant current corresponding to 1 C until the battery voltage reached 4.5 V. In addition, the current value corresponding to 0.1 C was calculated, a theoretical specific capacity of the LICoO₂ in charging at 4.5 V being 192 mAh/g. Next, constant current discharge was performed at the constant current corresponding to 1 C until the voltage reached 3.3 V. For every 50-cycle charge/discharge repetition, constant current discharge was performed at a constant current corresponding to 0.1 C until the battery voltage reached 3.3 V after constant current charge was performed at the constant current corresponding to 0.1 C until the voltage reached 4.5 V, and thereby, the discharge capacities [mAh] in the (50×n)th cycle were obtained. Next, by substituting these discharge capacities [mAh] in the following expression, the cycle capacity maintaining ratio/a/ were obtained.

Cycle capacity maintaining ratio(%)=[(discharge capacity in the(50×n)th cycle)/(discharge capacity in the first cycle)]×100

where n is an integer not less than 1

### (Results)

FIG. 11B shows relationship between average coverage ratios and capacity maintaining ratios regarding the coin cells in Examples 2-1 to 2-3 and Comparative Example 2-1. In addition, in FIG. 11B, two coin cells for each of Examples 2-1 to 2-3 and Comparative Example 2-1 were prepared and the results of the capacity maintaining ratios being evaluated are shown. Table 2 presents the evaluation results of the coin cells in Examples 2-1 to 2-3 and Comparative Example 2-1.

TABLE 2

| | Cycle | | | Capacity |
|---|---|---|---|---|
| | Number of | Average | Average | Maintaining Ratio |
| | ALD processes | Thickness | Coverage | (100 Cycles) |
| | [Times] | [nm] | Ratio [%] | [%] |
| Example 2-1 | 10 | 1.0 | 30 | 72 |
| Example 2-2 | | | 54 | 77 |
| Example 2-3 | | | 92 | 82 |
| Comparative | | | 0 | 59 |
| Example 2-1 | | | | |

The followings were apparent from Table 2 and FIG. 11B. As the average coverage ratio was higher, the capacity maintaining ratio tended to increase. When the average coverage ratio was 30% or more, the capacity maintaining ratio after 100 cycles was able to be improved up to 70% or more. When the average coverage ratio was 54% or more, the capacity maintaining ratio after 100 cycles was able to be improved up to 75% or more. Accordingly, in view of improvement of the capacity maintaining ratio, the average coverage ratio of the surface covering positive electrode active material particle was to fall preferably within a range of 30% or more, and still preferably within a range of 54% or more.

### <3. Relationship Between Average Coverage Ratio and Initial Capacity>

### Example 3-1

A coin cell was obtained similarly to Example 1-5 except that the average coverage ratio of the covered LiCoO₂ particle was made 19% by adjusting the degree of aggregation of the LiCoO₂ particle powder contained in the deposition chamber of the ALD apparatus.

### Example 3-2

A coin cell was obtained similarly to Example 3-1 except that the average coverage ratio of the covered LiCoO₂ particle was made 30% by adjusting the degree of aggregation of the LiCoO₂ particle powder contained in the deposition chamber of the ALD apparatus.

### Example 3-3

A coin cell was obtained similarly to Example 3-1 except that the average coverage ratio of the covered LiCoO₂ particle was made 77% by adjusting the degree of aggregation of the LiCoO₂ particle powder contained in the deposition chamber of the ALD apparatus.

### Example 3-4

A coin cell was obtained similarly to Example 3-1 except that the average coverage ratio of the covered LiCoO₂ particle was made 96% by adjusting the degree of aggregation of the LiCoO₂ particle powder contained in the deposition chamber of the ALD apparatus.

### Example 3-5

A coin cell was obtained similarly to Example 3-1 except that the average coverage ratio of the covered LiCoO₂ particle was made 99% by adjusting the degree of aggregation of the LiCoO₂ particle powder contained in the deposition chamber of the ALD apparatus.

### Comparative Example 3-1

A coin cell was obtained similarly to Example 3-1 except that the ALD process was omitted and the LiCoO₂ particle not covered with Al₂O₃ layer was used as the positive electrode active material.

### (Initial Capacity)

The initial capacities of the coin cells obtained as mentioned above were obtained similarly to that of the coin cell in Example 1-1. Then, the obtained initial capacities were evaluated on the basis of the criteria similarly to those for the coin cell in Example 1-1.

### (Results)

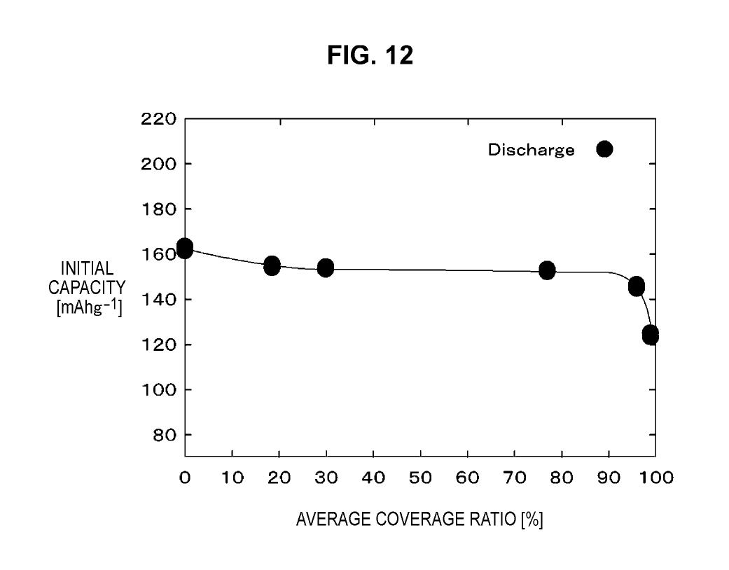

FIG. 12 shows relationship between average coverage ratios and initial capacities of regarding the coin cells in Examples 3-1 to 3-5 and Comparative Example 3-1. In addition, in FIG. 12, two coin cells for each of Examples 3-1 to 3-5 and Comparative Example 3-1 were prepared and the results of the initial capacities being obtained are shown. Table 3 presents the evaluation results of the coin cells in Examples 3-1 to 3-5 and Comparative Example 3-1.

TABLE 3

| | Cycle Number | Average | Average | Evaluation |
|---|---|---|---|---|
| | of ALD processes | Thickness | Coverage | of |
| | [Times] | [nm] | Ratio [%] | Initial Capacity |
| Example 3-1 | 50 | 5.0 | 19 | Excellent |
| Example 3-2 | | | 30 | Excellent |
| Example 3-3 | | | 77 | Excellent |
| Example 3-4 | | | 96 | Excellent |
| Example 3-5 | | | 99 | Good |
| Comparative | | | 0 | — |
| Example 3-1 | | | | |

The followings were apparent from Table 3 and FIG. 12. The initial capacity was substantially constant with respect to increase of the average coverage ratio within a range of the average coverage ratio being 0% or more and 96% or less. It was noted that the initial capacity tended to decrease slightly when the average coverage ratio exceeded 77%. Although the initial capacity tended to decrease when the average coverage ratio exceeded 96%, the rate of decrease was within 25%. Accordingly, in view of suppressing decrease in initial capacity caused by formation of the inorganic oxide layer, it was preferable for the covering state of the surface covering positive electrode active material particle to be in the incomplete covering state. Furthermore, the average coverage ratio of the surface covering positive electrode active material particle in the incomplete covering state was to fall preferably within a range of 96% or less, and still preferably within a range of 77% or less.

When the evaluation results in <2. Relationship between Average Coverage Ratio and Capacity Maintaining Ratio> and <3. Relationship between Average Coverage Ratio and Initial Capacity> were integrated, in view of improving the capacity maintaining ratio and suppressing decrease in initial capacity caused by the inorganic oxide layer, the average coverage ratio of the surface covering positive electrode active material particle was to fall preferably within a range of 30% or more and 96% or less, and still preferably within a range of 54% or more and 77% or less.

The embodiments of the present technology have been specifically described above. However, the present technology is not limited to the above-described embodiments. Various modifications of the present technology can be made without departing from the technical spirit of the present technology.

For example, the configurations, the methods, the processes, the shapes, the materials, the numerical values, and the like mentioned in the above-described embodiments are merely examples. Different configurations, methods, processes, shapes, materials, numerical values, and the like may be used, as necessary.

Further, configuration, methods, processes, shapes, materials, numerical values and the like in the above-described embodiments may be combined insofar as they are not departing from the spirit of the present technology.

It should be understood by those skilled in the art that various modifications, combinations, sub-combinations and alterations may occur depending on design requirements and other ratios insofar as they are within the scope of the appended claims or the equivalents thereof.

Additionally, the present technology may also be configured as below.

(1) A positive electrode active material including:

a particle containing a lithium-containing compound; and

an inorganic oxide layer provided on at least part of a surface of the particle,

wherein an average thickness of the inorganic oxide layer falls within a range of 0.2 nm or more and 5 nm or less.

(2) The positive electrode active material according to (1),

wherein the inorganic oxide layer is configured of deposited monolayers.

(3) The positive electrode active material according to (2),

wherein an average number of deposition of the monolayers falls within a range of 2 layers or more and 50 layers or less.

(4) The positive electrode active material according to any one of (1) to (3),

wherein a part of the surface of the particle is exposed from the inorganic oxide layer.

(5) The positive electrode active material according to (4),

wherein an average coverage ratio of the inorganic oxide layer falls within a range of 30% or more and 96% or less.

(6) The positive electrode active material according to any one of (4) to (5),

wherein the inorganic oxide layer has an opening part, and

wherein the part of the surface of the particle is exposed through the opening part.

(7) The positive electrode active material according to any one of (1) to (6),

wherein the inorganic oxide layer is a metal oxide layer.

(8) A positive electrode including:

a particle containing a lithium-containing compound; and

an inorganic oxide layer provided on at least part of a surface of the particle,

wherein an average thickness of the inorganic oxide layer falls within a range of 0.2 nm or more and 5 nm or less.

(9) A battery including:

a positive electrode;

a negative electrode; and

an electrolyte,

wherein the positive electrode includes
a particle containing a lithium-containing compound, and
an inorganic oxide layer provided on at least part of a surface of the particle,

wherein an average thickness of the inorganic oxide layer falls within a range of 0.2 nm or more and 5 nm or less.

(10) A battery pack including

the battery according to (9).

(11) An electronic device including

the battery according to (9),

wherein the device receives power supply from the battery.

(12) An electric vehicle including:

the battery according to (9);

a conversion device configured to perform conversion into driving power of the vehicle upon reception of power supply from the battery; and

a control device configured to perform information processing regarding vehicle control based on information regarding the battery.

(13) A power storage device including

the battery according to (9),

wherein the device supplies power to an electronic device connected to the battery.

(14) The power storage device according to (13), including

a power information control device configured to transmit and receive a signal to/from another device via a network,

wherein the power storage device performs charge/discharge control of the battery based on information received by the power information control device.

(15) A power system configured to receive power supply from the battery according to (9), or to allow power to be supplied to the battery from a power generation apparatus or a power network.
(16) A manufacturing method of a positive electrode active material, the method including

forming an inorganic oxide layer whose average thickness falls within a range of 0.2 nm or more and 5 nm or less by depositing monolayers on a surface of a particle containing a lithium-containing compound.

(17) The manufacturing method of a positive electrode active material according to (16),

wherein a method of depositing the monolayers is an atomic layer deposition method.

What is claimed is:

1. A positive electrode active material comprising:
a particle containing a lithium-containing compound; and
an inorganic oxide layer provided on at least part of a surface of the particle,
wherein an average thickness of the inorganic oxide layer falls within a range of 0.2 nm or more and 5 nm or less.

2. The positive electrode active material according to claim 1,
wherein the inorganic oxide layer is configured of deposited monolayers.

3. The positive electrode active material according to claim 2,
wherein an average number of deposition of the monolayers falls within a range of 2 layers or more and 50 layers or less.

4. The positive electrode active material according to claim 1,
wherein a part of the surface of the particle is exposed from the inorganic oxide layer.

5. The positive electrode active material according to claim 4,
wherein an average coverage ratio of the inorganic oxide layer falls within a range of 30% or more and 96% or less.

6. The positive electrode active material according to claim 4,
wherein the inorganic oxide layer has an opening part, and
wherein the part of the surface of the particle is exposed through the opening part.

7. The positive electrode active material according to claim 1,
wherein the inorganic oxide layer is a metal oxide layer.

8. A positive electrode comprising:
a particle containing a lithium-containing compound; and
an inorganic oxide layer provided on at least part of a surface of the particle,
wherein an average thickness of the inorganic oxide layer falls within a range of 0.2 nm or more and 5 nm or less.

9. A battery comprising:
a positive electrode;
a negative electrode; and
an electrolyte,
wherein the positive electrode includes
a particle containing a lithium-containing compound, and
an inorganic oxide layer provided on at least part of a surface of the particle,
wherein an average thickness of the inorganic oxide layer falls within a range of 0.2 nm or more and 5 nm or less.

10. A battery pack comprising
the battery according to claim 9.

11. An electronic device comprising
the battery according to claim 9,
wherein the device receives power supply from the battery.

12. An electric vehicle comprising:
the battery according to claim 9;
a conversion device configured to perform conversion into driving power of the vehicle upon reception of power supply from the battery; and
a control device configured to perform information processing regarding vehicle control based on information regarding the battery.

13. A power storage device comprising
the battery according to claim 9,
wherein the device supplies power to an electronic device connected to the battery.

14. The power storage device according to claim 13, comprising
a power information control device configured to transmit and receive a signal to/from another device via a network,
wherein the power storage device performs charge/discharge control of the battery based on information received by the power information control device.

15. A power system configured to receive power supply from the battery according to claim 9, or to allow power to be supplied to the battery from a power generation apparatus or a power network.

16. A manufacturing method of a positive electrode active material, the method comprising
forming an inorganic oxide layer whose average thickness falls within a range of 0.2 nm or more and 5 nm or less by depositing monolayers on a surface of a particle containing a lithium-containing compound.

17. The manufacturing method of a positive electrode active material according to claim 16,
wherein a method of depositing the monolayers is an atomic layer deposition method.
